(19) United States
(12) Patent Application Publication
(10) Pub. No.: US 2024/0324209 A1
(43) Pub. Date: Sep. 26, 2024

(54) SEMICONDUCTOR STORAGE DEVICE AND METHOD OF MANUFACTURING SEMICONDUCTOR STORAGE DEVICE

(71) Applicant: Kioxia Corporation, Tokyo (JP)

(72) Inventor: Akihito IKEDO, Yokkaichi Mie (JP)

(73) Assignee: Kioxia Corporation, Tokyo (JP)

(21) Appl. No.: 18/591,813

(22) Filed: Feb. 29, 2024

(30) Foreign Application Priority Data
Mar. 24, 2023 (JP) 2023-048297

(51) Int. Cl. H10B 43/27; H10B 43/35

(52) U.S. Cl. CPC H10B 43/27; H10B 43/35

(57) ABSTRACT

A semiconductor storage device includes: a first semiconductor layer; a second semiconductor layer disposed over the first semiconductor layer; a third semiconductor layer disposed over the second semiconductor layer; a stacked body disposed over the first to third semiconductor layers; a pillar penetrating through the stacked body and including a fourth semiconductor layer having a side surface in contact with the second semiconductor layer; and a dividing structure penetrating through the stacked body to reach the first semiconductor layer and separating the stacked body. The dividing structure includes a first portion and a second portion above the first portion, the first portion having a lower portion in contact with the first semiconductor layer and an upper portion located above an upper surface of the second semiconductor layer. A width of the upper portion of the first portion is greater than a width of the lower portion of the first portion.

### CROSS-REFERENCE TO RELATED APPLICATION

This application is based upon and claims the benefit of priority from Japanese Patent Application No. 2023-048297, filed Mar. 24, 2023, the entire contents of which are incorporated herein by reference.

### FIELD

Embodiments described herein relate generally to a semiconductor storage device and a method of manufacturing the semiconductor storage device.

### BACKGROUND

As types of semiconductor storage devices, 3-dimensional flash memories are known.

### DESCRIPTION OF THE DRAWINGS

FIG. 1 is a sectional view illustrating a semiconductor storage device according to a first embodiment;

FIG. 2 is a schematic sectional view illustrating a columnar portion in a memory cell portion;

FIG. 3 is a diagram illustrating a configuration of main units in a semiconductor device;

FIG. 4 is a sectional view illustrating another configuration of the main units in the Y direction;

FIG. 5 is a sectional view illustrating an example of a process of manufacturing the semiconductor device;

FIG. 6 is a sectional view illustrating an example of a process of manufacturing the semiconductor device;

FIG. 7 is a sectional view illustrating an example of a process of manufacturing the semiconductor device;

FIG. 8 is a sectional view illustrating an example of a process of manufacturing the semiconductor device;

FIG. 9 is a sectional view illustrating an example of a process of manufacturing the semiconductor device;

FIG. 10 is a sectional view illustrating an example of a process of manufacturing the semiconductor device;

FIG. 11 is a sectional view illustrating an example of a process of manufacturing the semiconductor device;

FIG. 12 is a sectional view illustrating an example of a process of manufacturing the semiconductor device;

FIG. 13 is a sectional view illustrating an example of a process of manufacturing the semiconductor device;

FIG. 14 is a sectional view illustrating an example of a process of manufacturing the semiconductor device;

FIG. 15 is a sectional view illustrating an example of a process of manufacturing the semiconductor device;

FIG. 16 is a sectional view illustrating an example of a process of manufacturing the semiconductor device;

FIG. 17 is a sectional view illustrating an example of a process of manufacturing the semiconductor device;

FIG. 18 is a sectional view illustrating an example of a process of manufacturing the semiconductor device;

FIG. 19 is a sectional view illustrating an example of a process of manufacturing the semiconductor device;

FIG. 20 is a sectional view illustrating an example of a process of manufacturing the semiconductor device;

FIG. 21 is a sectional view illustrating a configuration of main units in the Y direction according to a second embodiment;

FIG. 22 is a sectional view illustrating another configuration of the main units in the Y direction;

FIG. 23 is a sectional view illustrating an example of a process of manufacturing the semiconductor device;

FIG. 24 is a sectional view illustrating an example of a process of manufacturing the semiconductor device;

FIG. 25 is a sectional view illustrating an example of a process of manufacturing the semiconductor device;

FIG. 26 is a sectional view illustrating an example of a process of manufacturing the semiconductor device;

FIG. 27 is a sectional view illustrating an example of a process of manufacturing the semiconductor device;

FIG. 28 is a sectional view illustrating an example of a process of manufacturing the semiconductor device;

FIG. 29 is a sectional view illustrating an example of a process of manufacturing the semiconductor device;

FIG. 30 is a sectional view illustrating an example of a process of manufacturing the semiconductor device;

FIG. 31 is a sectional view illustrating an example of a process of manufacturing the semiconductor device;

FIG. 32 is a sectional view illustrating an example of a process of manufacturing the semiconductor device;

FIG. 33 is a sectional view illustrating an example of a process of manufacturing the semiconductor device;

FIG. 34 is a sectional view illustrating an example of a process of manufacturing the semiconductor device;

FIG. 35 is a sectional view illustrating an example of a process of manufacturing the semiconductor device;

FIG. 36 is a sectional view illustrating an example of a process of manufacturing the semiconductor device;

FIG. 37 is a sectional view illustrating an example of a process of manufacturing the semiconductor device;

FIG. 38 is a sectional view illustrating an example of a process of manufacturing the semiconductor device;

FIG. 39 is a sectional view illustrating a configuration of main units in the Y direction according to a third embodiment;

FIG. 40 is a sectional view illustrating another configuration of the main units in the Y direction;

FIG. 41 is a sectional view illustrating an example of a process of manufacturing the semiconductor device;

FIG. 42 is a sectional view illustrating an example of a process of manufacturing the semiconductor device;

FIG. 43 is a sectional view illustrating an example of a process of manufacturing the semiconductor device;

FIG. 44 is a sectional view illustrating an example of a process of manufacturing the semiconductor device;

FIG. 45 is a sectional view illustrating an example of a process of manufacturing the semiconductor device;

FIG. 46 is a sectional view illustrating an example of a process of manufacturing the semiconductor device;

FIG. 47 is a sectional view illustrating an example of a process of manufacturing the semiconductor device;

FIG. 48 is a sectional view illustrating an example of a process of manufacturing the semiconductor device;

FIG. 49 is a sectional view illustrating an example of a process of manufacturing the semiconductor device;

FIG. 50 is a sectional view illustrating an example of a process of manufacturing the semiconductor device;

FIG. 51 is a sectional view illustrating an example of a process of manufacturing the semiconductor device;

FIG. 52 is a diagram illustrating an example of a short region;

FIG. 53 is a sectional view illustrating an example of a mark of a sacrifice layer pattern; and

FIG. 54 is a sectional view illustrating an example of a mark of a pattern of a slit.

### DETAILED DESCRIPTION

Embodiments provide a semiconductor storage device and a method of manufacturing storage device capable of reducing a risk of bending a cantilever during replacement.

In general, according to one embodiment, a semiconductor storage device includes: a first semiconductor layer; a second semiconductor layer disposed over the first semiconductor layer; a third semiconductor layer disposed over the second semiconductor layer; a stacked body disposed over the first to third semiconductor layers and including a plurality of electrode films and a plurality of insulating films stacked alternately in a first direction; a pillar penetrating through the stacked body in the first direction, and including a fourth semiconductor layer having a side surface in contact with the second semiconductor layer; and a dividing structure penetrating through the stacked body in the first direction to reach the first semiconductor layer, separating the stacked body in a second direction intersecting the first direction, and further extending in a third direction intersecting the first and second directions. The dividing structure includes a first portion and a second portion located above the first portion, the first portion having a lower portion in contact with the first semiconductor layer and an upper portion located above an upper surface of the second semiconductor layer. A width of the upper portion of the first portion in the second direction is greater than a width of the lower portion of the first portion in the second direction.

### First Embodiment

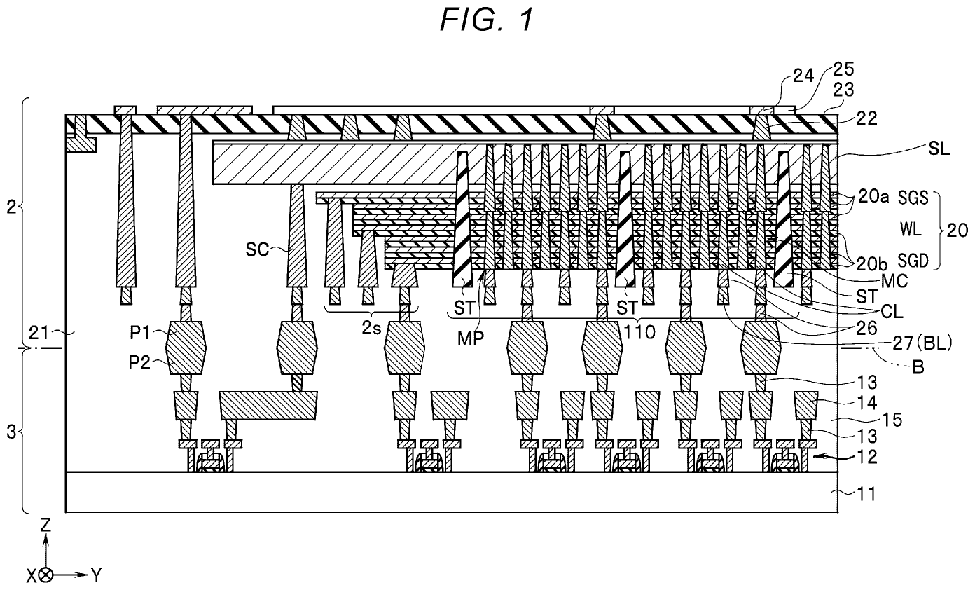

FIG. 1 is a sectional view illustrating a semiconductor storage device 1 according to a first embodiment.

Hereinafter, a stacking direction of a stacked body 20 to be described below is referred to as the Z direction. One direction intersecting, for example, orthogonal to the Z direction is referred to the Y direction. One direction orthogonal to each of the Z and Y directions is referred to as the X direction.

As illustrated in FIG. 1, the semiconductor storage device 1 includes a memory chip 2 and a controller chip 3. The memory chip 2 and the controller chip 3 are pasted on a pasting surface B and are electrically connected via a pasting electrode P1, a pasting electrode P2, and a wiring connected to the pasting electrode P1 and the pasting electrode P2 pasted on the pasting surface B. FIG. 1 illustrates the memory chip 2 mounted on an upper surface of the controller chip 3.

The controller chip 3 includes a substrate 11, a processing circuit 12, a via 13, a wiring 14, the pasting electrode P2, and an inter-layer insulating film 15.

The substrate 11 is, for example, a semiconductor substrate such as a silicon substrate. The processing circuit 12 includes a transistor provided on the substrate 11. The processing circuit 12 may further include semiconductor elements such as a resistant element and a capacity element provided on the substrate 11 in addition to the transistor.

The via 13 electrically connects the processing circuit 12 and the wiring 14, and the wiring 14 and the pasting electrode P2. The wiring 14 and the pasting electrode P2 form a multi-layer wiring structure in the inter-layer insulating film 15. The pasting electrode P2 is buried in the inter-layer insulating film 15. At least a part of the surface of the pasting electrode P2 is exposed to be substantially flush with the surface of the inter-layer insulating film 15. The wiring 14 and pasting electrode P2 are electrically connected to the processing circuit 12 or the like. For example, a low-resistant metal such as copper or tungsten is used for the via 13, the wiring 14, and the pasting electrode P2. The inter-layer insulating film 15 covers the processing circuit 12, the via 13, and the wiring 14 for protection. For example, an insulating film such as a silicon oxide film is used for the inter-layer insulating film 15.

The memory chip 2 includes a stacked body 20, a columnar portion CL, a slit ST, a source layer SL, an inter-layer insulating film 21, a contact 22, an insulating film 23, a wiring 24, an insulating film 25, a via 26, and a wiring 27.

The stacked body 20 is provided above the processing circuit 12 and is located in the Z direction with respect to the substrate 11. The stacked body 20 includes a plurality of electrode films 20a and a plurality of insulating films 20b alternately stacked in the Z direction. For example, a conductive metal such as tungsten is used for the electrode film 20a. For example, an insulating film such as a silicon oxide is used for the insulating film 20b. The insulating film 20b insulates the electrode films 20a from each other. That is, the plurality of electrode films 20a are stacked in an insulating state. The stacking numbers of electrode films 20a and insulating films 20b are any number. The insulating film 20b may be, for example, a porous insulating film or an air gap.

In FIG. 1, 2s is a step portion of the electrode film 20a provided to connect a contact to each electrode film 20a. The memory chip 2 includes a source contact SC. One end of the source contact SC is electrically connected to the source layer SL and the other end of the source contact SC is electrically connected to the pasting electrode P1.

One or a plurality of electrode films 20a at the upper end and the lower end of the stacked body 20 in the Z direction function as a source-side select gate SGS and a drain-side select gate SGD, respectively. The electrode films 20a between the source-side select gate SGS and the drain-side select gate SGD function as word lines WL. The word line WL is a gate electrode of a memory cell MT. The drain-side select gate SGD is a gate electrode of a drain-side select transistor. The source-side select gate SGS is a gate electrode of a source-side select transistor. The source-side select gate SGS is provided in an upper region of the stacked body 20. The drain-side select gate SGD is provided in a lower region of the stacked body 20. The lower region is a region of the stacked body 20 closer to the controller chip 3 and the upper region is a region of the stacked body 20 farther from the controller chip 3 (closer to the contact 22 and the insulating film 25).

As described above, the semiconductor storage device 1 includes the plurality of memory cells MT connected in series between a source-side select transistor ST2, a drain-side select transistor ST1. A NAND string NS has a structure in which the source-side select transistor ST2, the memory cells MT, and the drain-side select transistor ST1 are connected in series. The NAND string NS is connected to, for example, a bit line BL via the via 26. The bit line BL is the wiring 27 provided below the stacked body 20 and extending in the Y direction.

The plurality of columnar portions CL are provided inside the stacked body 20. The columnar portions CL extends to penetrate through the stacked body 20 in a stacking direction (Z direction) of the stacked body 20 in the stacked body 20 and is provided from the via 26 connected to the bit line BL to the source layer SL. In the embodiment, the columnar portion CL grows to be divided in two steps in the Z direction for a high aspect ratio. However, the columnar portion CL may grow in one step. The source-side select transistor ST2 and the drain-side select transistor contain a part of the columnar portion CL.

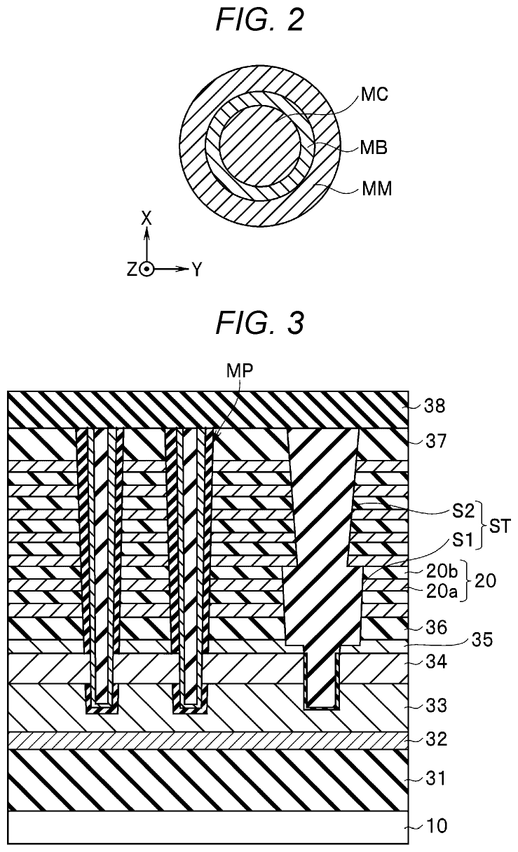

FIG. 2 is a schematic sectional view illustrating the columnar portion CL in a memory cell portion. Each of the plurality of columnar portions CL is provided in a memory hole MH provided in the stacked body 20. The plurality of columnar portions CL each include a semiconductor body MB, a memory film MM, and a core layer MC. The columnar portion CL includes the core layer MC provided in its center, the semiconductor body (semiconductor member) MB provided around the core layer MC, and the memory film (charge storage member) MM provided around the memory body MB. The semiconductor body MB is electrically connected to the source layer SL. The memory film MM is provided between the semiconductor body BM and the electrode film 20a and is, for example, a stacking layer including a tunnel insulating film, a charge trapping film, and a block insulating film from the outside. A shape of the memory hole MH on an X-Y plane is, for example, circular or elliptical.

Referring back to FIG. 1, the plurality of slits ST are provided in the stacked body 20. The slit ST extends in the X direction and penetrates through the stacked body 20 in the stacking direction (Z direction) of the stacked body 20. The inside of the slit ST is filled with an insulating material such as a silicon oxide, and the insulating material is configured in a plate shape. The stacked body 20 is divided for each block BLK by the slit ST. The slit ST electrically isolates the electrode film 20a of the stacked body 20. Two adjacent slits ST form a plurality of slits ST with one block BLK interposed therebetween.

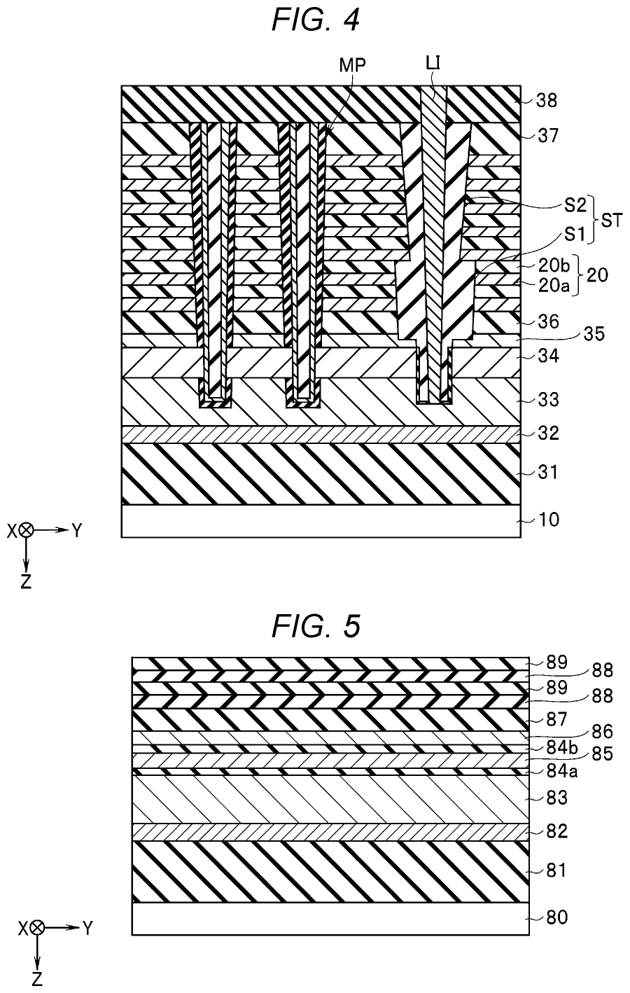

Next, a configuration of main units in the semiconductor device according to the first embodiment will be described with reference to FIG. 3. FIG. 3 is a sectional view illustrating a configuration of the main units in the Y direction. Here, the slit ST and a memory pillar MP are illustrated for description. FIG. 4 is a sectional view illustrating another configuration of main units in the Y direction according to the first embodiment.

An insulating layer 31 is provided on the silicon substrate 10. The insulating layer 31 includes, for example, a silicon oxide layer.

A plurality of conductive layers 32, 33, 34, and 35 are provided on the insulating layer 31. Specifically, the conductive layer 32 is provided on the insulating layer 31. The conductive layer 33 is provided on the conductive layer 32. The conductive layer 34 is provided on the conductive layer 33. Further, the conductive layer 35 is provided on the conductive layer 34. The conductive layers 32, 33, 34, and 35 function as a source line SL.

The conductive layer 32 is formed of, for example, a tungsten silicide (WSi) containing a metal. The conductive layer 32 may not be provided. The conductive layers 33 and 34 include, for example, polycrystalline silicon layer with impurity. The impurity is, for example, phosphorus (P) or an arsenic (As). The conductive layer 35 includes, for example, a polycrystalline silicon layer with no impurity.

An insulating layer 36 is provided on the conductive layer 35. The insulating layer 36 includes, for example, a silicon oxide layer.

A plurality of electrode films 20a and a plurality of insulating films 20b that form the stacked body 20 are alternatively stacked on the insulating layer 36. The electrode film 20a includes, for example, tungsten (W). The insulating film 20b includes, for example, a silicon oxide film. An insulating layer 37 is provided on the electrode film 20a. The insulating layer 38 is provided on the insulating layer 37. The insulating layers 37 and 38 include a silicon oxide film, for example.

The memory pillar MP is provided in the conductive layers 33 to 35, the plurality of electrode films 20a, the plurality of insulating films 20b, and the insulating layer 37. The memory pillar MP has a columnar structure extending in the Z direction orthogonal to the silicon substrate 10.

The slit ST electrically isolates the stacked body 20 of the memory cell array in units of blocks. The slit ST is provided in the conductive layers 33 to 35, the insulating layer 36, the stacked body 20, and the insulating layer 37. The slit ST has a plate structure extending in the X and Z directions.

The slit ST has a 2-step shape including a first shape (first portion) S1 and a second shape (second portion) S2 provided on the first shape S1. The first shape S1 is provided in the conductive layers 33 to 35, the insulating layer 36, and the insulating film 20b of the next bottommost step from the lower side. In the first shape S1, a width of the upper surface is greater than a width of a bottom surface (or a lower surface) on a cross section along the Y direction. In the first shape S1, an upper width in the conductive layer 35 is greater than a lower width in the conductive layer 35.

The second shape S2 is provided in the insulating layer 37 and the insulating film 20b of the electrode film 20a above the insulating film 20b of the next bottommost step from the lower side. In the second shape S2, a width of the upper surface is greater than a bottom surface (or a lower surface) on a cross section along the Y direction. Further, the width of the upper surface of the first shape S1 is greater than the width of the lower surface of the second shape S2.

A boundary between the first shape S1 and the second shape S2 is in a boundary (or a space) between the second insulating film 20b from the lower side and the third electrode film 20a from the lower side. The first shape S1 and the second shape S2 include, for example, an insulating layer such as a silicon oxide layer.

The memory pillar MP and the slit ST have a shape tapered downward. Therefore, since the length of a cantilever of a lower layer is longer than the length of a cantilever of an upper layer, the cantilevers may be bent during replacement.

In the embodiment, by causing the width of the first shape S1 of a slit widening portion to be greater than the width of the second shape, the length of the cantilever of the lower layer is shortened, and thus it is possible to reduce a risk of bending the cantilever during replacement.

As illustrated in FIG. 4, a wiring LI may be formed by burying a conductive film penetrating through the insulating layer 38, the insulating layer 37, and the inside and bottom of the slit ST and reaching the conductive layer 33, so that a voltage is supplied to the source line SL (the conductive layers 32, 33, 34, and 35).

Next, a method of manufacturing the semiconductor device according to the first embodiment will be described with reference to FIGS. 5 to 20. FIGS. 5 to 20 are sectional views illustrating examples of processes of manufacturing the semiconductor device according to the first embodiment.

First, as illustrated in FIG. 5, a silicon oxide film 81, a tungsten silicide film 82, a polysilicon film 83, a silicon oxide film 84a, a polysilicon film (or a silicon nitride film) 85, a silicon oxide film 84b, a polysilicon film 86, and a silicon oxide film 87 are formed in this order on the upper surface of the semiconductor substrate 80 by a chemical vapor deposition (CVD) technology or the like. Subsequently, silicon nitride films 88 and silicon oxide films 89 are alternately formed on the upper surface of the silicon oxide film 87 by a CVD technology or the like. In FIG. 5, as an example, a stacking film including the silicon nitride films 88 and the silicon oxide films 89 has a structure of two layers. The number of stacking films may be three or more.

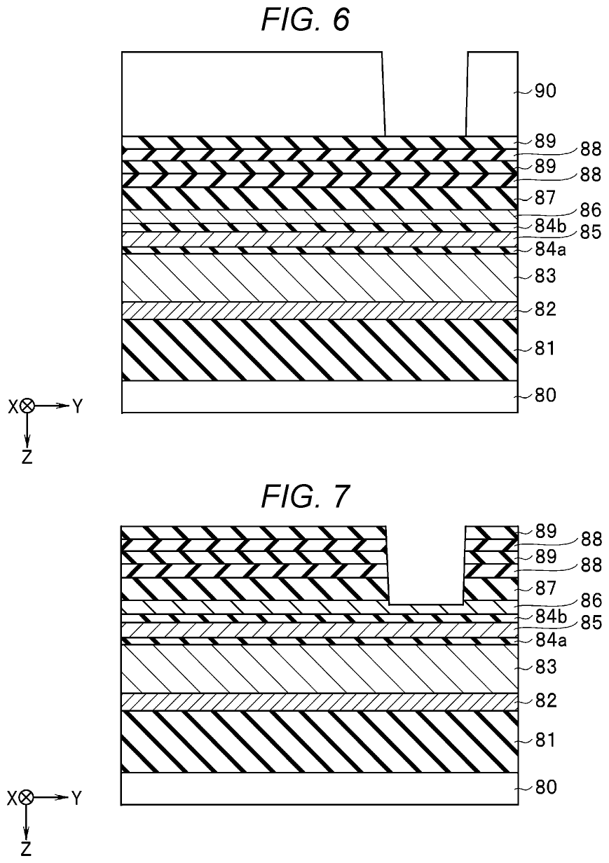

Subsequently, as illustrated in FIG. 6, an etching mask film 90 is formed on the upper surface of the uppermost silicon oxide film 89. The etching mask film 90 is, for example, an amorphous carbon film. The etching mask film 90 of a region where the slit widening portion (the first shape S1) is formed is selectively removed by a photolithographic technology and an anisotropic etching technology such as a reactive ion etching (RIE). The etching mask film 90 may be a resist film. When the etching mask film 90 is a resist film, the etching mask film 90 is formed by only a photolithographic technology. For example, after a resist is applied to the surface of the uppermost silicon oxide film 89 by a spin coat method or the like and pre-baking is performed, a pattern of the slit widening portion is transferred to the resist by an exposure technology. A developer is infiltrated and the resist in a region where a groove for the slit widening portion is formed is removed to form the etching mask film 90. At this time, the width of an opening is wider than the width of the slit ST to be formed later.

Subsequently, a region exposed from the opening of the etching mask film 90 is etched downward by an anisotropic etching technology. That is, the stacking film including the silicon nitride films 88 and the silicon oxide films 89 is etched in the order of the silicon oxide film 87 and the polysilicon film 86. At this time, half-etching is performed so that the polysilicon film 86 is not penetrated. By this etching, the polysilicon film 86 is exposed on the bottom surface of the opening. When the above-described etching ends, the etching mask film 90 is removed by an anisotropic etching technology, an ashing technology, or the like (FIG. 7). By this etching, the groove for the slit widening portion is formed.

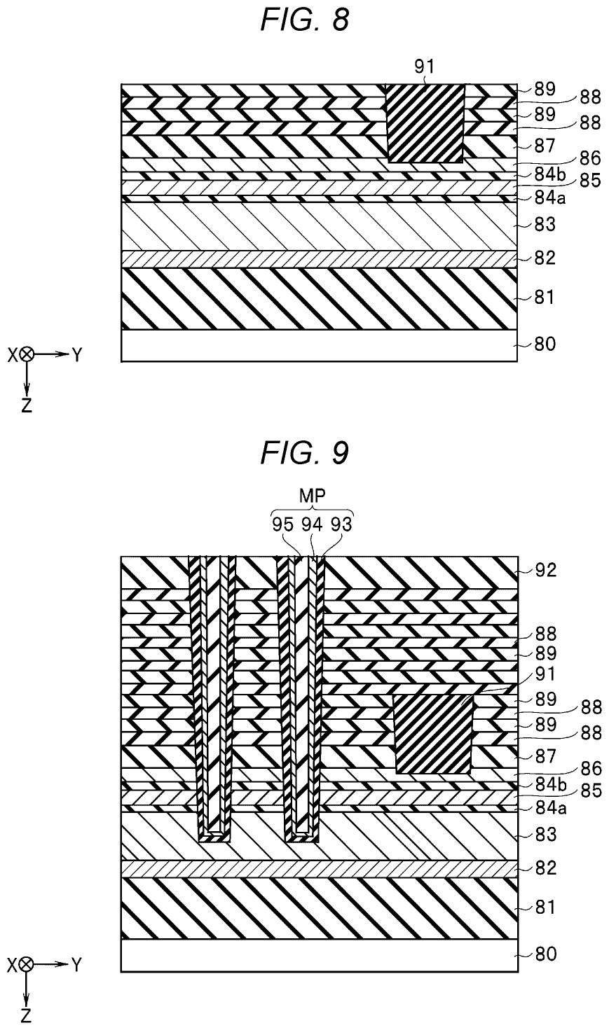

Subsequently, a silicon nitride film 91 is formed on the entire upper surface of the semiconductor substrate 80 by a CVD technology or the like. Subsequently, the silicon nitride film 91 is etched using the silicon oxide film 89 as a stopper by an anisotropic etching technology, a chemical mechanical polishing (CMP) technology, or the like. The silicon nitride film 91 above the position of the upper surface of the silicon oxide film 89 (the uppermost silicon oxide film 89 when the plurality of silicon oxide films 89 are formed) is removed by etching, and the silicon nitride film 91 is buried in the groove for the slit widening portion, as illustrated in FIG. 8.

Subsequently, the silicon nitride films 88 and the silicon oxide films 89 are alternately formed by a CVD technology or the like. FIG. 9 illustrates, for example, a structure in which a stacking film including the silicon nitride films 88 and the silicon oxide films 89 is formed by five layers. Further, a silicon oxide film 92 is formed by a CVD technology or the like. An etching mask film (not illustrated) that has an opening in a region where the memory hole MH is formed is formed by a photolithographic technology, and the memory hole MH is formed by an anisotropic etching technology such as reactive ion etching (RIE). Specifically, a region exposed from an opening of the etching mask film (not illustrated) is first etched downward. That is, the silicon oxide film 92, the plurality of stacking films including the silicon nitride films 88 and the silicon oxide films 89, the silicon oxide film 87, the polysilicon film 86, the silicon oxide film 84b, the polysilicon film 85, the silicon oxide film 84a, and the polysilicon film 83 are etched in this order. At this time, half-etching is performed so that the polysilicon film 83 is not penetrated. By this etching, the polysilicon film 83 is exposed on the bottom surface of the opening. The etching mask film is removed by an anisotropic etching technology, an ashing technology, or the like.

Subsequently, the memory pillar MP is formed in the memory hole MH. The memory pillar MP includes a memory film 93, a channel body film 94, and a core insulating film 95. First, a silicon oxide film (block insulating film), a silicon nitride film (charge trap film), and a silicon oxide film (tunnel insulating film) are formed in this order by an atomic layer deposition (ALD) method or the like. The memory film 93 is formed by these three films. Further, a polysilicon film (the channel body film 94) and a silicon oxide film (the core insulating film 95) are formed in this order by an ALD method or the like. These films are etched using the silicon oxide film 92 as a stopper by an anisotropic etching technology, a CMP technology, or the like. A film above the position of the upper surface of the silicon oxide film 92 is removed by etching, and the memory pillar MP is formed in the memory hole MH, as illustrated in FIG. 9.

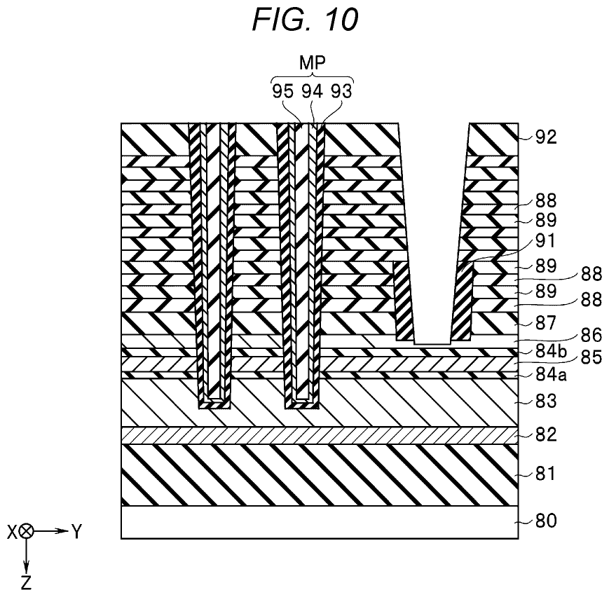

Subsequently, an etching mask film (not illustrated) that has an opening in a region where the slit ST is formed is formed by a photolithographic technology, and the slit ST is formed by an anisotropic etching technology such as reactive ion etching (RIE). At this time, the width of the opening is narrower than the width of the groove for the slit widening portion. The slit ST is formed in two steps. First, as etching of the first step, a region exposed from the opening is etched downward halfway in the polysilicon film 86. That is, the silicon oxide film 92, the plurality of stacking films including the silicon nitride films 88 and the silicon oxide films 89, the silicon nitride film 91, and the polysilicon film 86 are etched in this order. At this time, half-etching is performed so that the polysilicon film 86 is not penetrated. By this etching, the polysilicon film 86 is exposed on the bottom surface of the opening (FIG. 10).

Although not illustrated in FIG. 9, before the slit ST is formed, a silicon oxide film (not illustrated) is formed to cover the silicon oxide film 92 and the memory pillar MP. Accordingly, it is possible to prevent infiltration of the polysilicon film (or the silicon nitride film) in the memory pillar MP with a chemical removing the silicon film (or the silicon nitride film) 85 via the formed slit ST. In other embodiments, the forming of the silicon oxide film is not illustrated similarly.

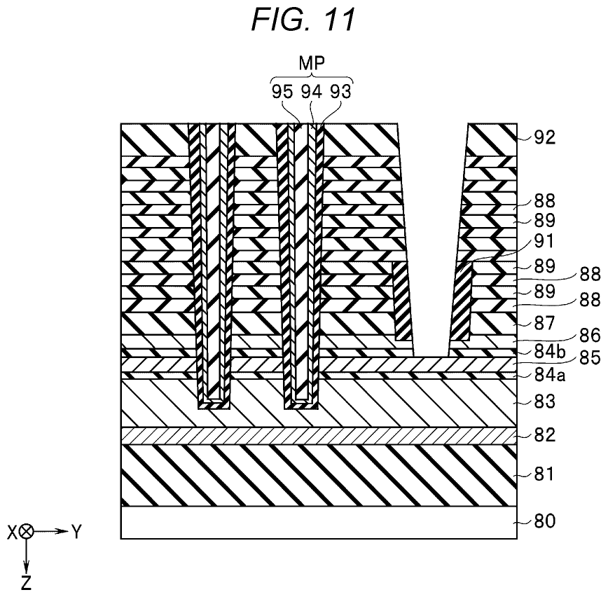

Subsequently, as etching of the second step, a region exposed from the opening is etched further downward. That is, the polysilicon film 86 and the silicon oxide film 84b are etched using the polysilicon film 85 as a stopper. By this etching, the polysilicon film 85 is exposed on the bottom surface of the opening. Then, the etching mask film is removed by an anisotropic etching technology, an ashing technology, or the like (FIG. 11).

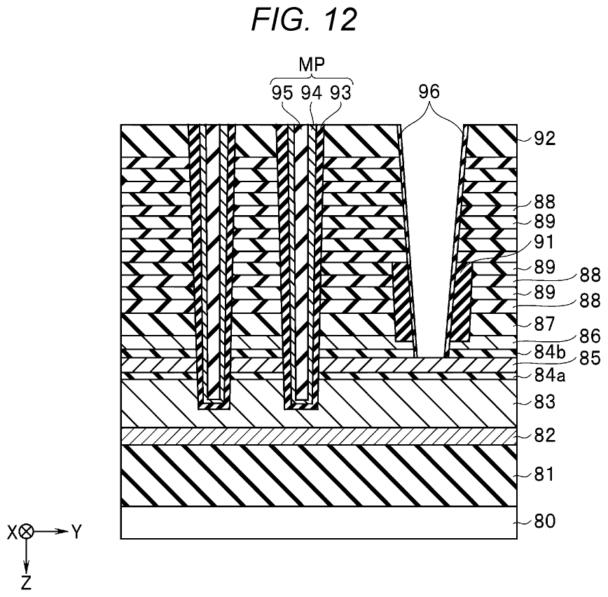

Subsequently, a silicon nitride film 96 is formed on the entire upper surface of the surface exposed above the semiconductor substrate 80 by a CVD technology or the like. That is, the silicon nitride film 96 is formed on the upper surface of the silicon oxide film 92 and the side surface and the bottom surface of the slit ST. Subsequently, the silicon nitride film 96 is etched back by an anisotropic etching technology. Accordingly, the silicon nitride film 96 can remain by selectively removing the silicon nitride film 96 on the upper surface of the silicon oxide film 92 and the side surface of the slit ST (FIG. 12).

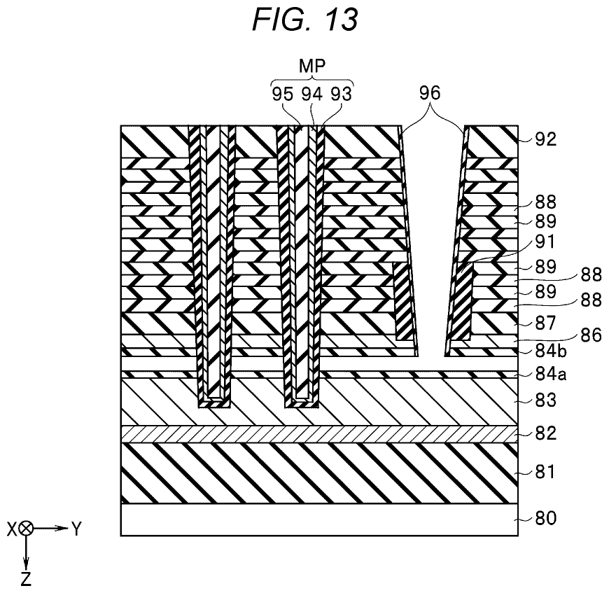

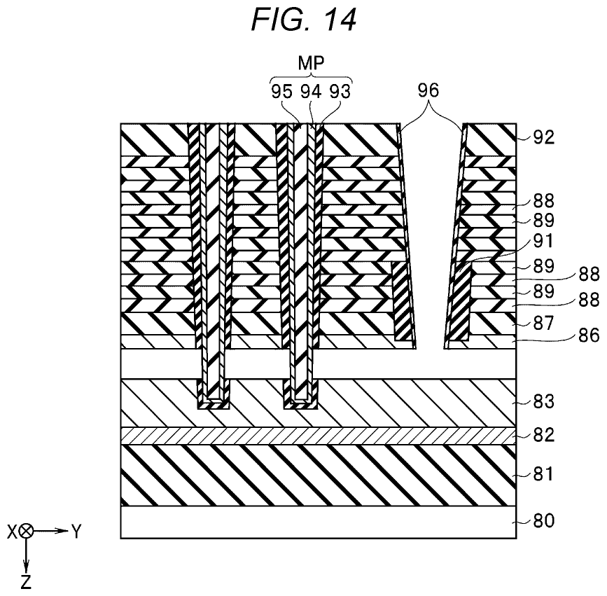

Subsequently, the polysilicon film 85 is etched with a chemical by an isotropic etching technology or the like (FIG. 13). Accordingly, a part of the outside wall of the memory pillar MP is exposed to a cavity portion in which the polysilicon film 85 is removed. Subsequently, the memory film 93 exposed to the cavity portion in which the polysilicon film 85 is removed and the silicon oxide films 84a and 84b are removed with a chemical by an isotropic etching technology. Accordingly, a part of the memory film 93 is removed and the channel body film 94 is exposed to the cavity portion (FIG. 14). The silicon nitride film 96 formed on the side surface of the slit ST prevents etching of the silicon oxide films 87, 89, and 92 stacked on the side of the slit ST when the memory film 93 is etched.

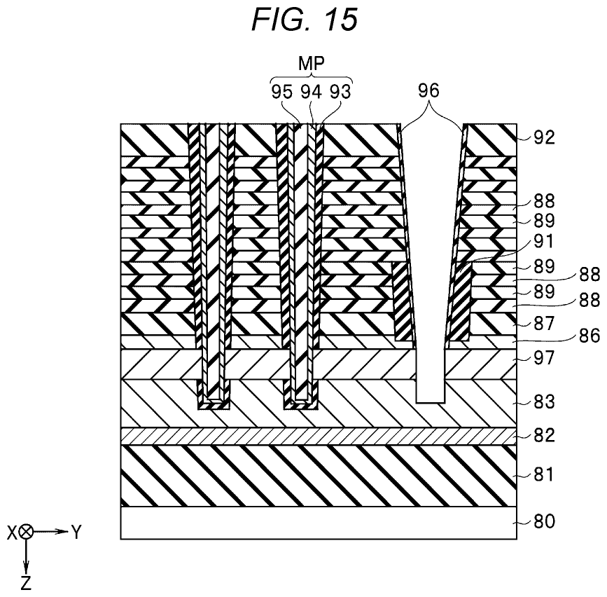

Subsequently, the cavity portion in which the polysilicon film 85 is removed is filled with the polysilicon film 97 by a CVD technology or the like. Accordingly, four conductive films of the tungsten silicide film 82, the polysilicon film 83, the polysilicon film 97, and the polysilicon film 86 are stacked. These conductive films function as the source line SL. By filling the cavity portion with the polysilicon film 97, the source line SL and the channel body film 94 are electrically connected. Subsequently, the entire surface is etched back by an anisotropic etching technology to remove the polysilicon film 85 formed on the surface of the silicon oxide film 92 or in the slit ST. By the etch-back processing, the polysilicon film 83 below the slit ST is also partially removed. That is, by the half-etching of the polysilicon film 83, the polysilicon film 83 is exposed from the bottom surface and the side surface in the vicinity of the bottom surface of the slit ST (FIG. 15).

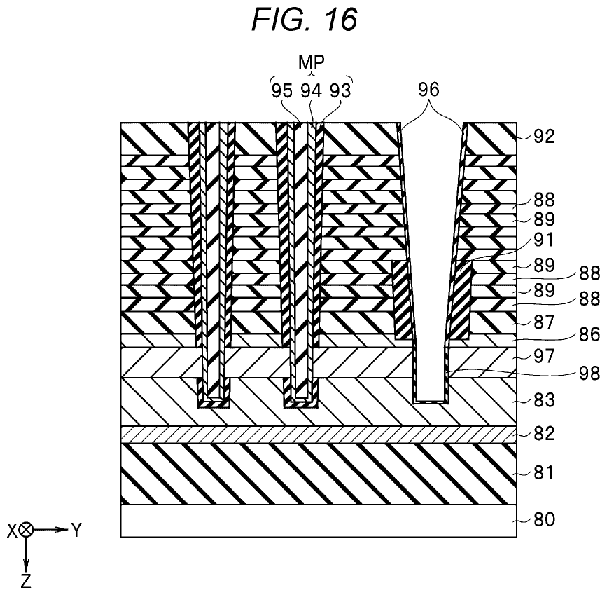

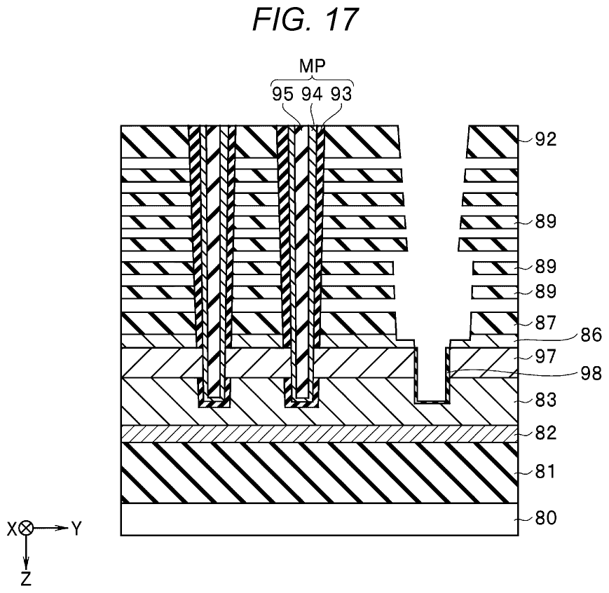

Subsequently, a thermal oxide film 98 is formed on the surfaces of the polysilicon films 83, 97, and 86 exposed to the inner wall (the bottom surface or the side surface) of the slit ST by thermal oxide processing (FIG. 16). Subsequently, the silicon nitride film is selectively removed with a chemical or the like by an isotropic etching technology. By the isotropic etching technology, the silicon nitride film 96 formed on the side surface of the slit ST is removed. The silicon nitride film 91 of the widening portion is also removed. Further, the silicon nitride film 88 exposed to the side surface of the slit ST is removed. Accordingly, the cavity portion is formed in a region interposed by the inside of the slit ST and the upper and lower portions of the silicon oxide films 87, 89, and 92 (FIG. 17).

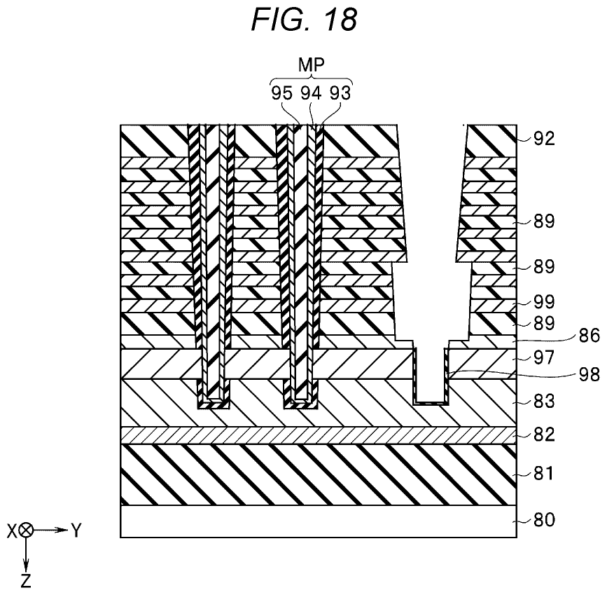

Subsequently, the cavity portion in which the silicon nitride film 88 is removed is filled with a conductive film 99 such as a tungsten film by a CVD technology or the like. The conductive film 99 functions as the source-side select gate SGS, the drain-side select gate SGD, and the word line WL. Subsequently, the entire surface is etched back by an anisotropic etching technology or the like to remove the conductive film 99 formed on the surface of the silicon oxide film 92 or in the slit ST (FIG. 18).

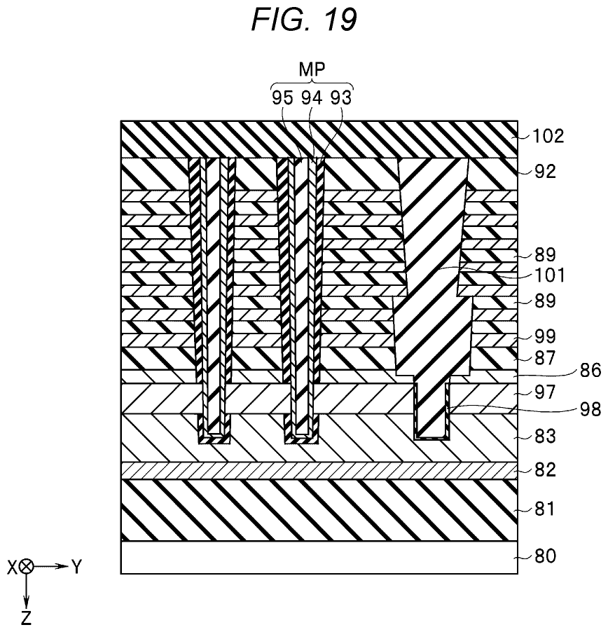

Subsequently, a silicon oxide film 101 is formed by a CVD technology or the like. Subsequently, the silicon oxide film 101 is etched by a CMP technology or the like. Accordingly, the silicon oxide film 101 is buried in the slit ST. Finally, a silicon oxide film 102 is formed on the entire upper surface of the semiconductor substrate 80 by a CVD technology or the like to cover the upper surface of the memory pillar MP with the insulating film, and then the formation of the slit ST ends (FIG. 19). The structure illustrated in FIG. 3 is formed by performing the foregoing procedure.

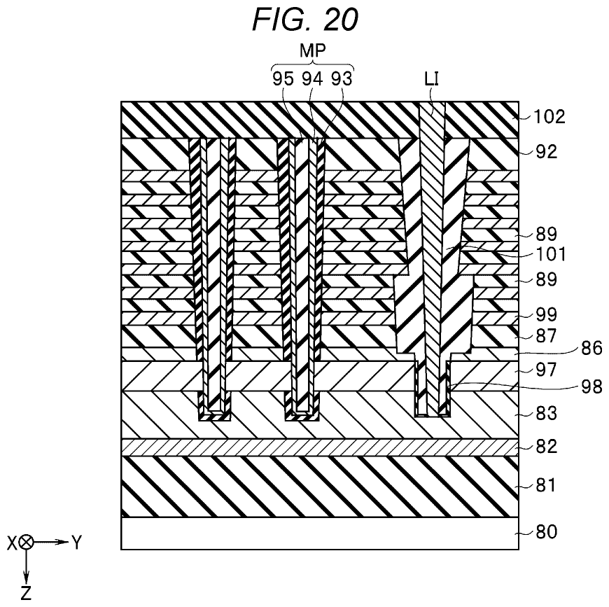

When the wiring LI through which a voltage is supplied to the source line SL is formed from a writing (not illustrated) formed above the silicon oxide film 102, a groove penetrating through the silicon oxide film 102 and the silicon oxide film 101 in the slit ST and reaching the polysilicon film 83 on the bottom of the slit ST is formed by a photolithographic technology, an etching technology, or the like. A conductive film is buried in the groove to form the wiring LI (FIG. 20). The structure illustrated in FIG. 4 is formed by performing the foregoing procedure.

### Second Embodiment

Next, a configuration of main units in a semiconductor device according to a second embodiment will be described with reference to FIG. 21. FIG. 21 is a sectional view illustrating a configuration of the main units in the Y direction according to the second embodiment. FIG. 22 is a sectional view illustrating another configuration of the main units in the Y direction according to the second embodiment.

In the second embodiment, a form of the first shape S1 of the slit ST is different from that of the first embodiment. As illustrated in FIG. 21, the first shape S1 is provided in the conductive layers 33, 34, and 35, the insulating layer 36, and the insulating film 20b of a second step from the lower side. The first shape S1 has a shape tapered gradually from the upper layer to the lower layer. The other structure is similar to that of the first embodiment.

As illustrated in FIG. 21, the wiring LI is formed by burying a conductive film penetrating through the insulating layer 38, the insulating layer 37, the inside and bottom of the slit ST and reaching the conductive layer 33, so that a voltage is supplied to the source line SL (the conductive layers 32, 33, 34, and 35).

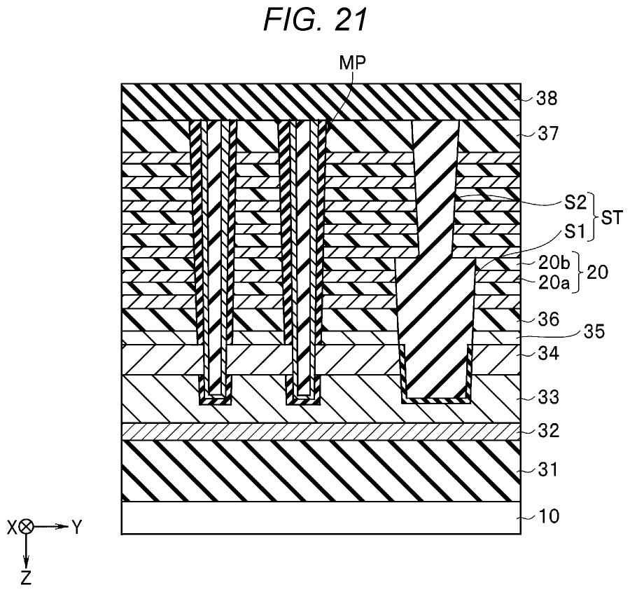

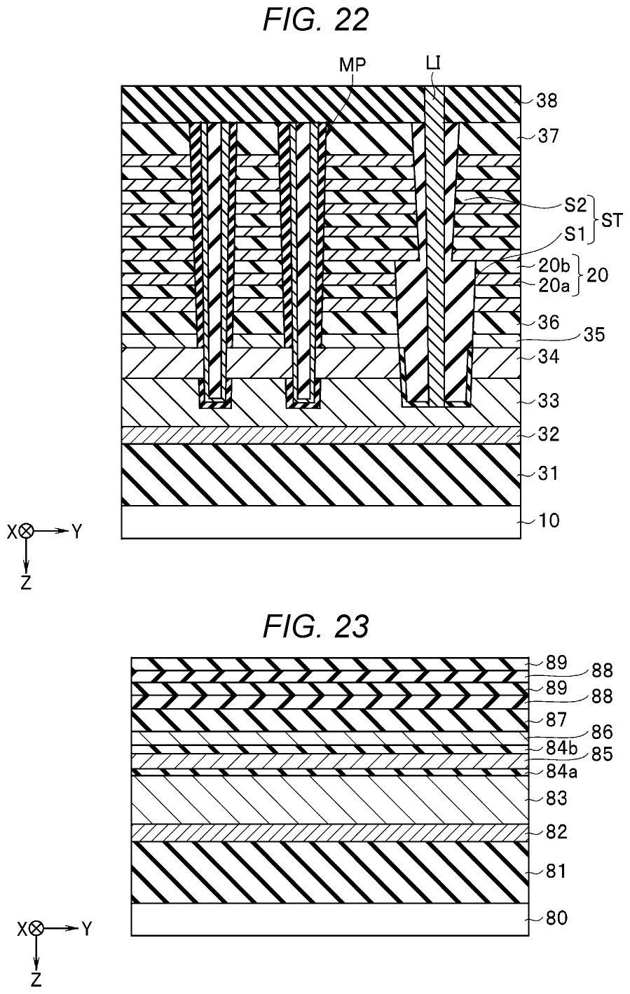

Next, a method of manufacturing the semiconductor device according to the second embodiment will be described with reference to FIGS. 23 to 38. FIGS. 23 to 38 are sectional views illustrating examples of processes of manufacturing the semiconductor device according to the second embodiment.

First, as illustrated in FIG. 23, the silicon oxide film 81, the tungsten silicide film 82, the polysilicon film 83, the silicon oxide film 84a, the polysilicon film 85, the silicon oxide film 84b, the polysilicon film 86, and the silicon oxide film 87 are formed in this order on the upper surface of the semiconductor substrate 80 by a chemical vapor deposition (CVD) technology or the like. Subsequently, silicon nitride films 88 and silicon oxide films 89 are alternately formed on the upper surface of the silicon oxide film 87 by a CVD technology or the like. In FIG. 23, as an example, a stacking film including the silicon nitride films 88 and the silicon oxide films 89 has a structure of two layers. The number of stacking films may be three or more.

Subsequently, as illustrated in FIG. 24, an etching mask film 90 is formed on the upper surface of the uppermost silicon oxide film 89. The etching mask film 90 is, for example, an amorphous carbon film. The etching mask film 90 of a region where the slit widening portion is formed is selectively removed by a photolithographic technology and an anisotropic etching technology such as a reactive ion etching (RIE). The etching mask film 90 may be a resist film. When the etching mask film 90 is a resist film, the etching mask film 90 is formed by only a photolithographic technology. For example, after a resist is applied to the surface of the uppermost silicon oxide film 89 by a spin coat method or the like and pre-baking is performed, a pattern of the slit widening portion (the first shape S1) is transferred to the resist by an exposure technology. A developer is infiltrated and the resist in a region where a groove for the slit widening portion is formed is removed to form the etching mask film 90. At this time, the width of an opening is wider than the width of the slit ST to be formed later.

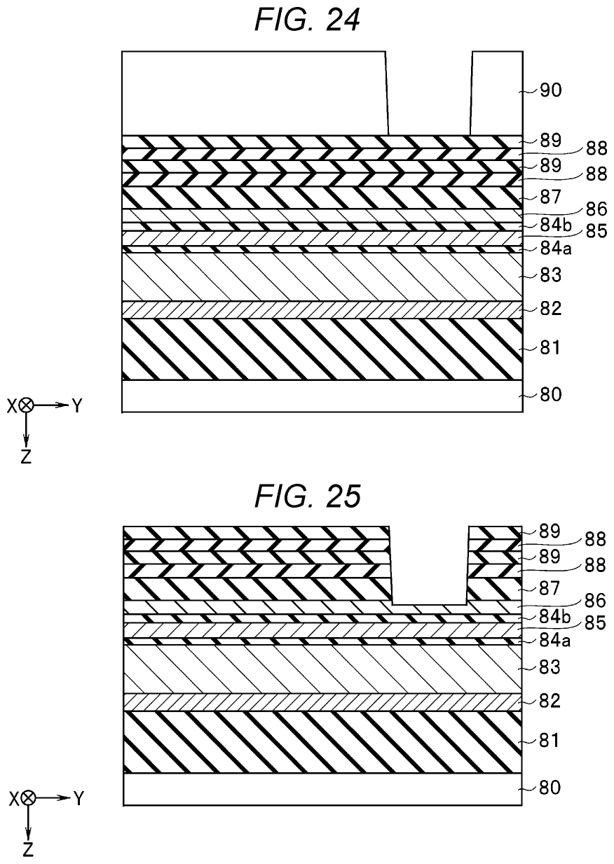

Subsequently, a region exposed from the opening of the etching mask film 90 is etched downward by an anisotropic etching technology. That is, the stacking film including the silicon nitride films 88 and the silicon oxide films 89 is etched in the order of the silicon oxide film 87 and the polysilicon film 86. At this time, half-etching is performed so that the polysilicon film 86 is not penetrated. By this etching, the polysilicon film 86 is exposed on the bottom surface of the opening. When the above-described etching ends, the etching mask film 90 is removed by an anisotropic etching technology, an ashing technology, or the like (FIG. 25). By this etching, the groove for the slit widening portion is formed.

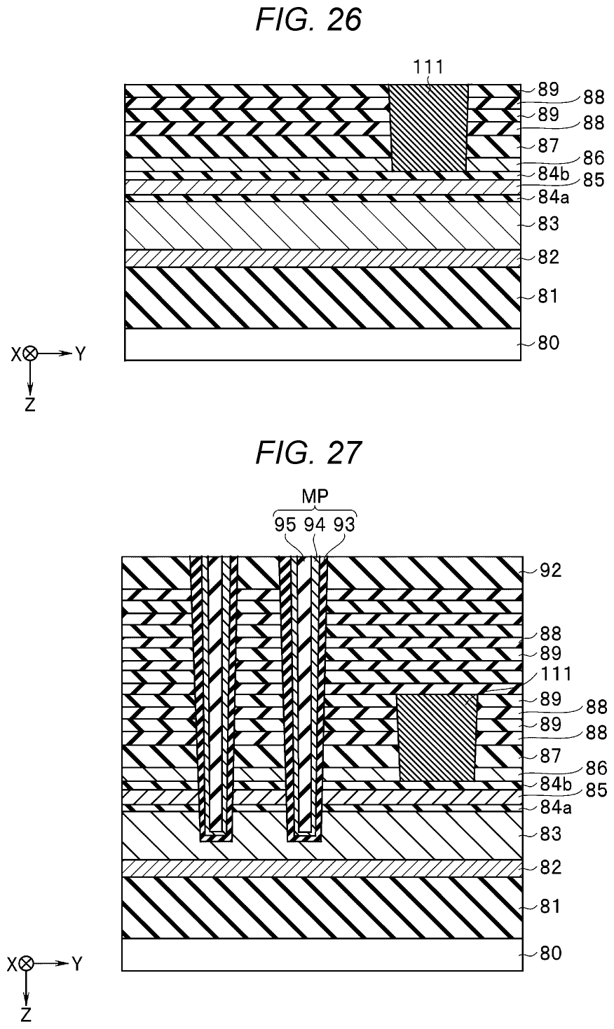

Subsequently, the silicon nitride film 91 is formed on the entire upper surface of the semiconductor substrate 80 by a CVD technology or the like. Subsequently, the silicon nitride film 91 is etched using the silicon oxide film 89 as a stopper by an anisotropic etching technology, a chemical mechanical polishing (CMP) technology, or the like. The silicon nitride film 91 above the position of the upper surface of the silicon oxide film 89 (the uppermost silicon oxide film 89 when the plurality of silicon oxide films 89 are formed) is removed by etching, and a polysilicon film 111 is buried in the groove for the slit widening portion, as illustrated in FIG. 26. Instead of the polysilicon film 111, a tungsten film may be buried in the groove for the slit widening portion.

Subsequently, the silicon nitride films 88 and the silicon oxide films 89 are alternately formed by a CVD technology or the like. FIG. 27 illustrates, for example, a structure in which a stacking film including the silicon nitride films 88 and the silicon oxide films 89 is formed by five layers. Further, the silicon oxide film 92 is formed by a CVD technology or the like. An etching mask film (not illustrated) that has an opening in a region where the memory hole MH is formed is formed by a photolithographic technology, and the memory hole MH is formed by an anisotropic etching technology such as reactive ion etching (RIE). Specifically, a region exposed from an opening of the etching mask film (not illustrated) is first etched downward. That is, the silicon oxide film 92, the plurality of stacking films including the silicon nitride films 88 and the silicon oxide films 89, the silicon oxide film 87, the polysilicon film 86, the silicon oxide film 84b, the polysilicon film 85, the silicon oxide film 84a, and the polysilicon film 83 are etched in this order. At this time, half-etching is performed so that the polysilicon film 83 is not penetrated. By this etching, the polysilicon film 83 is exposed on the bottom surface of the opening. The etching mask film is removed by an anisotropic etching technology, an ashing technology, or the like.

Subsequently, the memory pillar MP is formed in the memory hole MH. The memory pillar MP includes the memory film 93, the channel body film 94, and the core insulating film 95. First, a silicon oxide film (block insulating film), a silicon nitride film (charge trap film), and a silicon oxide film (tunnel insulating film) are formed in this order by an atomic layer deposition (ALD) method or the like. The memory film 93 is formed by these three films. Further, a polysilicon film (the channel body film 94) and a silicon oxide film (the core insulating film 95) are formed in this order by an ALD method or the like. These films are etched using the silicon oxide film 92 as a stopper by an anisotropic etching technology, a CMP technology, or the like. A film above the position of the upper surface of the silicon oxide film 92 is removed by etching, and the memory pillar MP is formed in the memory hole MH, as illustrated in FIG. 27.

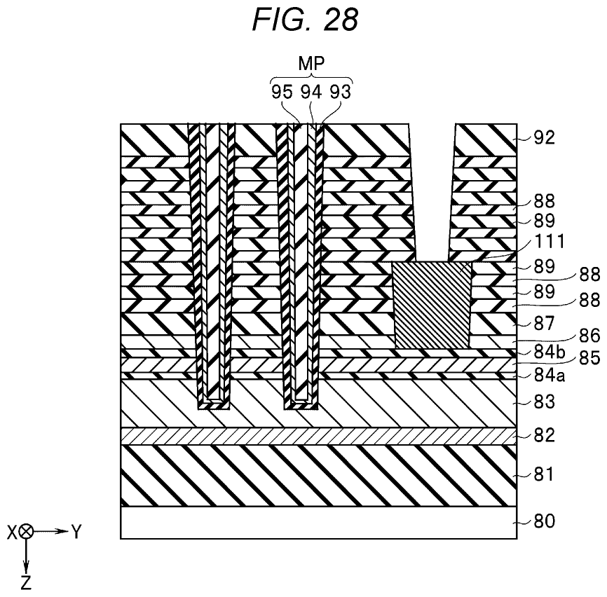

Subsequently, an etching mask film (not illustrated) that has an opening in a region where the slit ST is formed is formed by a photolithographic technology, and the slit ST is formed by an anisotropic etching technology such as reactive ion etching (RIE). At this time, the width of the opening is narrower than the width of the groove for the slit widening portion. In the forming of the slit ST, a region exposed from the opening is etched until the upper surface (the surface of the widening portion) of the polysilicon film 111. That is, the silicon oxide film 92, the plurality of stacking films including the silicon nitride films 88 and the silicon oxide films 89 are etched in this order. By the etching, the polysilicon film 111 is exposed to the bottom surface of the opening. Then, the etching mask film is removed by an anisotropic etching technology, an ashing technology, or the like (FIG. 28).

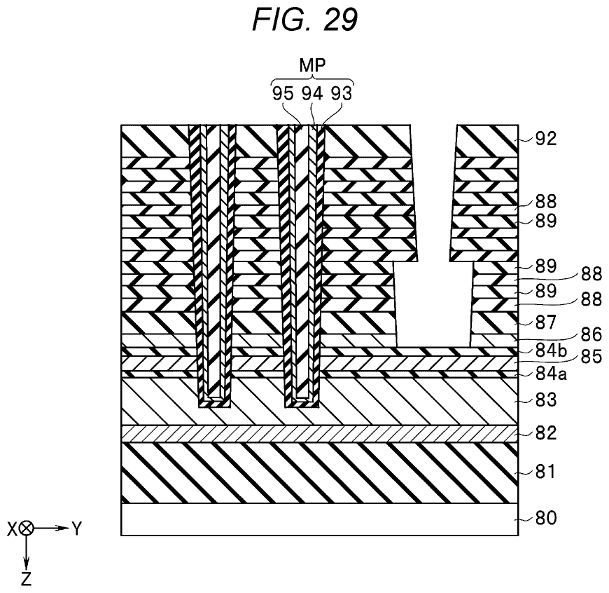

Subsequently, the polysilicon film 111 is etched with a chemical or the like by an isotropic etching technology (FIG. 29).

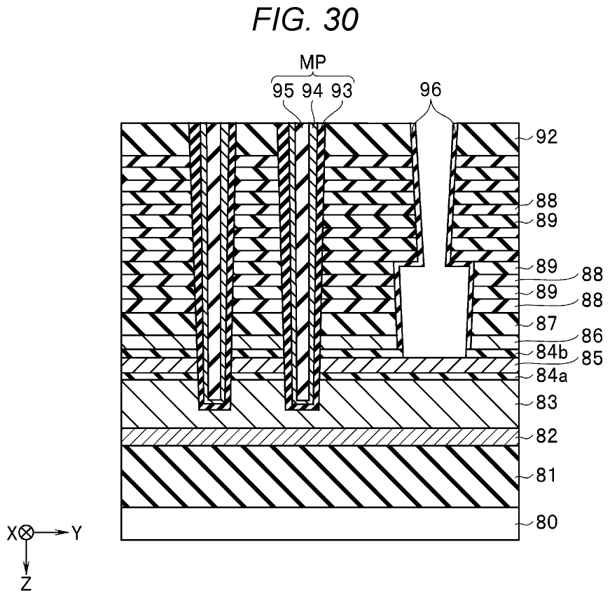

Subsequently, a silicon nitride film 96 is formed on the entire upper surface exposed above the semiconductor substrate 80 by a CVD technology or the like. That is, the silicon nitride film 96 is formed on the upper surface of the silicon oxide film 92 and the side surface and the bottom surface of the slit ST. Subsequently, the silicon nitride film 96 is etched back by an anisotropic etching technology. Accordingly, the silicon nitride film 96 can remain by selectively removing the silicon nitride film 96 on the upper surface of the silicon oxide film 92 and the side surface of the slit ST. Subsequently, the silicon oxide film 84b on the bottom surface of the slit ST is removed by an anisotropic etching technology or the like of self-alignment (FIG. 30). The silicon nitride film 96 and the silicon oxide film 84b may be continuously removed by over-etching during the etch-back.

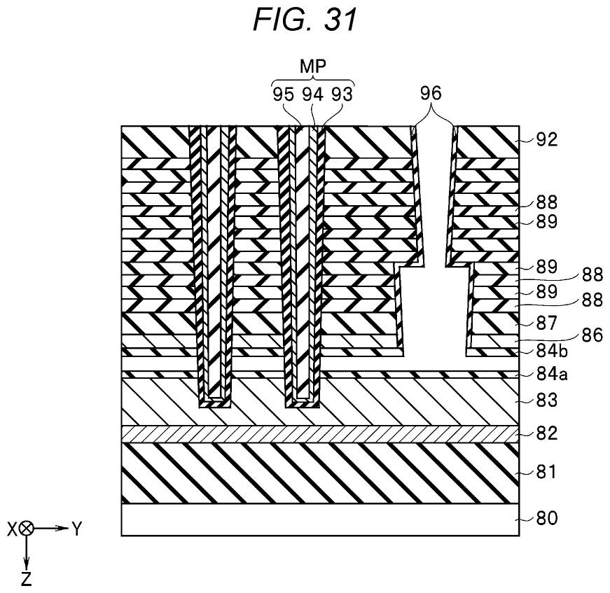

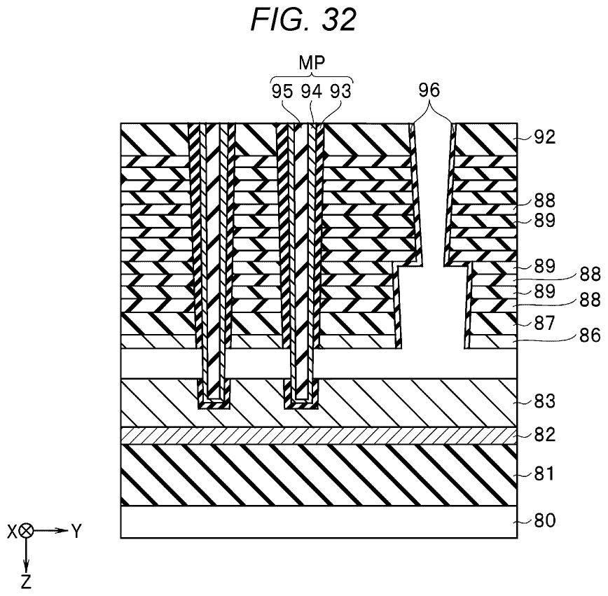

Subsequently, the polysilicon film 85 is etched with a chemical by an isotropic etching technology or the like (FIG. 31). Accordingly, a part of the outside wall of the memory pillar MP is exposed to a cavity portion in which the polysilicon film 85 is removed. Subsequently, the memory film 93 exposed to the cavity portion in which the polysilicon film 85 is removed and the silicon oxide films 84a and 84b are removed with a chemical by an isotropic etching technology. Accordingly, a part of the memory film 93 is removed and the channel body film 94 is exposed to the cavity portion (FIG. 32). The silicon nitride film 96 formed on the side surface of the slit ST prevents etching of the silicon oxide films 87, 89, and 92 stacked on the side of the slit ST when the memory film 93 is etched.

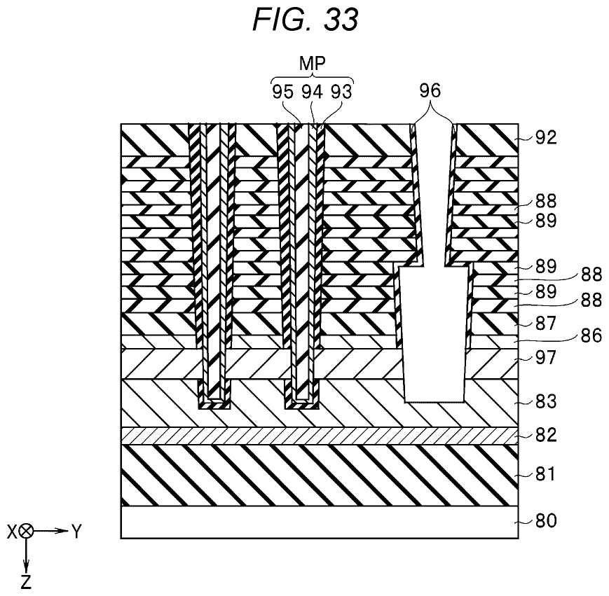

Subsequently, the cavity portion in which the polysilicon film 85 is removed is filled with the polysilicon film 97 by a CVD technology or the like. Accordingly, four conductive films of the tungsten silicide film 82, the polysilicon film 83, the polysilicon film 97, and the polysilicon film 86 are stacked. These conductive films function as the source line SL. By filling the cavity portion with the polysilicon film 97, the source line SL and the channel body film 94 are electrically connected. Subsequently, the entire surface is etched back by an anisotropic etching technology to remove the polysilicon film 85 formed on the surface of the silicon oxide film 92 or in the slit ST. By the etch-back processing, the polysilicon film 83 below the slit ST is also partially removed. That is, by the half-etching of the polysilicon film 83, the polysilicon film 83 is exposed from the bottom surface and the side surface in the vicinity of the bottom surface of the slit ST (FIG. 33).

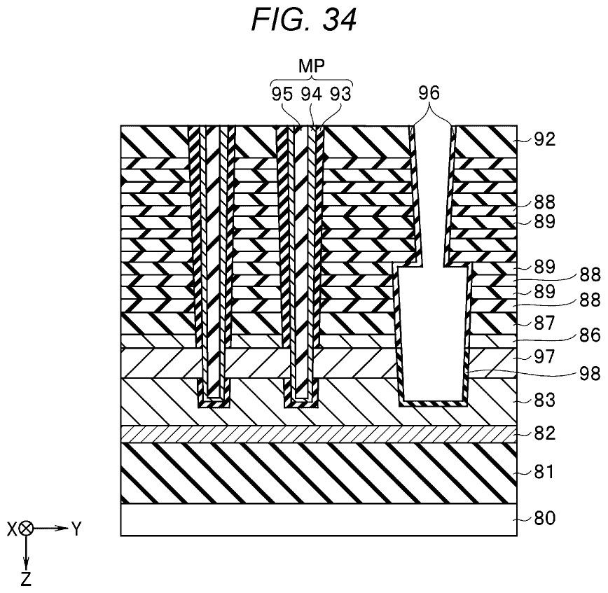

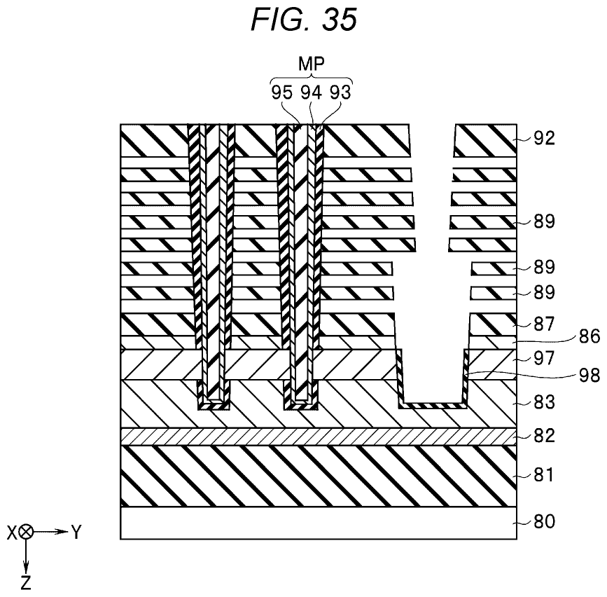

Subsequently, the thermal oxide film 98 is formed on the surfaces of the polysilicon films 83, 97, and 86 exposed to the inner wall (the bottom surface or the side surface) of the slit ST by thermal oxide processing (FIG. 34). Subsequently, the silicon nitride film is selectively removed with a chemical or the like by an isotropic etching technology. By the isotropic etching technology, the silicon nitride film 96 formed on the side surface of the slit ST is removed. The silicon nitride film 91 of the widening portion is also removed. Further, the silicon nitride film 88 exposed to the side surface of the slit ST is removed. Accordingly, the cavity portion is formed in a region interposed by the inside of the slit ST and the upper and lower portions of the silicon oxide films 87, 89, and 92 (FIG. 35).

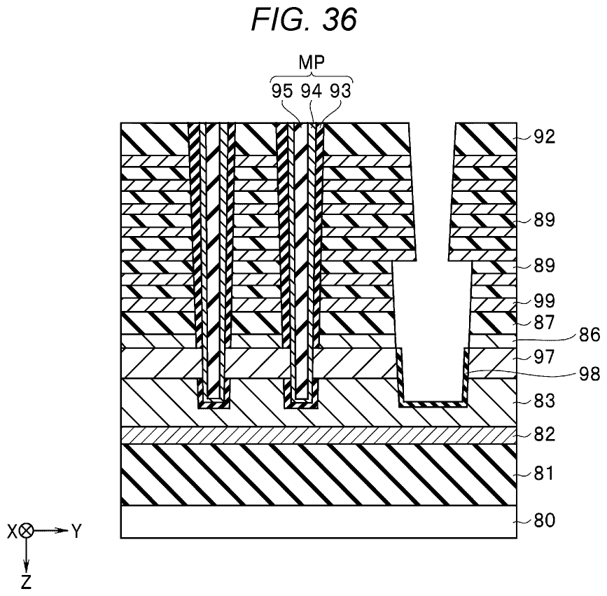

Subsequently, the cavity portion in which the silicon nitride film 88 is removed is filled with a conductive film 99 such as a tungsten film by a CVD technology or the like. The conductive film 99 functions as the source-side select gate SGS, the drain-side select gate SGD, and the word line WL. Subsequently, the entire surface is etched back by an anisotropic etching technology or the like to remove the conductive film 99 formed on the surface of the silicon oxide film 92 or in the slit ST (FIG. 36).

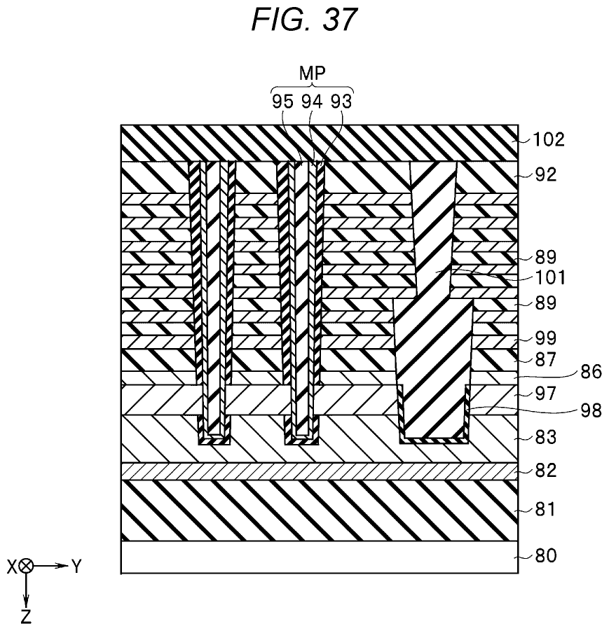

Subsequently, the silicon oxide film 101 is formed by a CVD technology or the like. Subsequently, the silicon oxide film 101 is etched by a CMP technology or the like. Accordingly, the silicon oxide film 101 is buried in the slit ST. Finally, the silicon oxide film 102 is formed on the entire upper surface of the semiconductor substrate 80 by a CVD technology or the like to cover the upper surface of the memory pillar MP with the insulating film, and then the formation of the slit ST ends (FIG. 37). The structure illustrated in FIG. 21 is formed by performing the foregoing procedure.

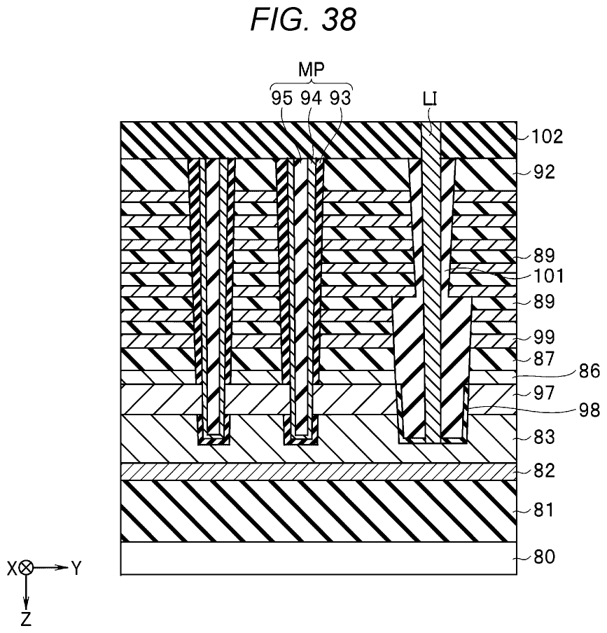

When the wiring LI through which a voltage is supplied to the source line SL is formed from a writing (not illustrated) formed above the silicon oxide film 102, a groove penetrating through the silicon oxide film 102 and the silicon oxide film 101 in the slit ST and reaching the polysilicon film 83 on the bottom of the slit ST is formed by a photolithographic technology, an etching technology, or the like. A conductive film is buried in the groove to form the wiring LI (FIG. 38). The structure illustrated in FIG. 22 is formed by performing the foregoing procedure.

### Third Embodiment

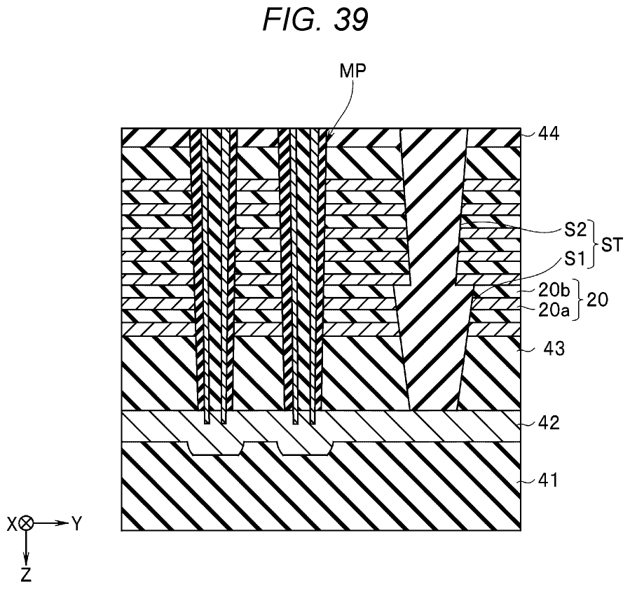

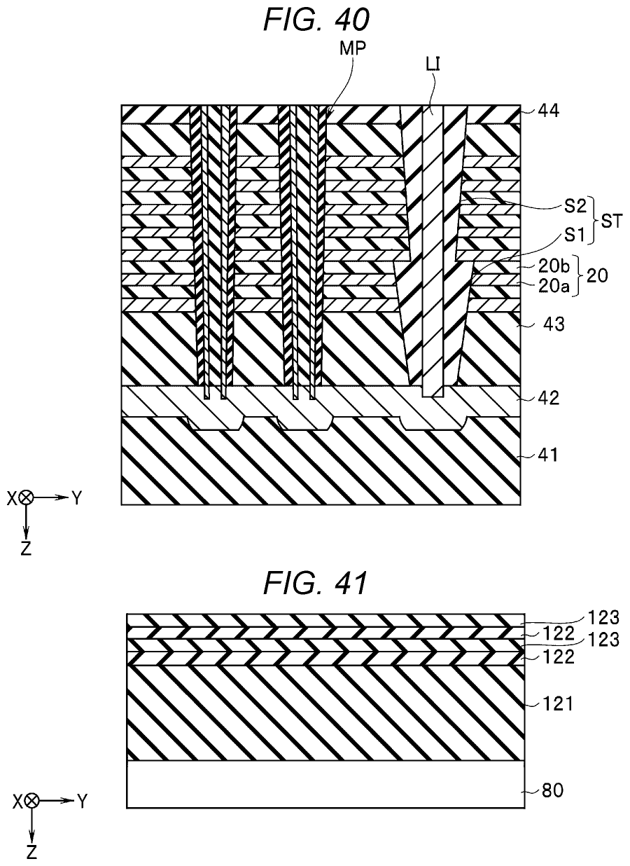

Next, a configuration of main units in a semiconductor device according to a third embodiment will be described with reference to FIG. 39. FIG. 39 is a sectional view illustrating a configuration of the main units in the Y direction according to the embodiment. FIG. 40 is a sectional view illustrating another configuration of the main units in the Y direction according to the third embodiment.

A conductive layer 42 is provided on an insulating layer 41. An insulating layer 43 is provided on the conductive layer 42. A plurality of electrode films 20a and a plurality of insulating films 20b that form the stacked body 20 are alternatively stacked on the insulating layer 43. An insulating layer 44 is provided on the electrode film 20a.

The memory pillar MP is provided in the insulating layer 43, the plurality of electrode films 20a, the plurality of insulating films 20b, and the insulating layer 44. The memory pillar MP has a columnar structure extending in the Z direction orthogonal to the surface of the insulating layer 41. A part of the channel body film of the memory pillar MP is protruded (exposed) from the insulating layer 43 and is connected to the conductive layer 42.

The slit ST is provided in the insulating layer 43, the stacked body 20, and the insulating layer 44. The slit ST has a 2-step shape including the first shape S1 and the second shape S2 provided on the first shape S1.

The first shape S1 is provided in the insulating layer 43 and the insulating film 20b of the second step from the lower side. In the first shape S1, a width of the upper surface is greater than a width of a bottom surface (or a lower surface) on a cross section along the Y direction.

The second shape S2 is provided in the insulating layer 44 and the insulating film 20b of the electrode film 20a above the insulating film 20b of the second step. In the second shape S2, a width of the upper surface is greater than the width of a bottom surface (or a lower surface) on a cross section along the Y direction. Further, the width of the upper surface of the first shape S1 is greater than the width of the lower surface of the second shape S2.

The slit ST electrically isolates the stacked body 20 of the memory cell array in units of blocks. The slit ST is provided in the conductive layers 33 to 35, the insulating layer 36, the stacked body 20, and the insulating layer 37. The slit ST has a plate structure extending in the X and Z directions.

The slit ST has a 2-step shape including the first shape S1 and the second shape S2 provided on the first shape S1. The first shape S1 is provided in the conductive layers 33, 34, and 35, the insulating layer 36, and the insulating film 20b of the second step from the lower side. In the first shape S1, a width of the upper surface is greater than a width of a bottom surface (or a lower surface) on a cross section along the Y direction. In the first shape S1, an upper width in the conductive layer 35 is greater than a lower width in the conductive layer 35.

The second shape S2 is provided in the insulating layer 37 and the insulating film 20b of the electrode film 20a above the insulating film 20b of the second step. In the second shape S2, a width of the upper surface is greater than a width of a bottom surface (or a lower surface) on a cross section along the Y direction. Further, the width of the upper surface of the first shape S1 is greater than the width of the lower surface of the second shape S2.

A boundary between the first shape S1 and the second shape S2 is in a boundary (or a space) between the second insulating film 20b from the lower side and the third electrode film 20a from the lower side. The first shape S1 and the second shape S2 include, for example, an insulating layer such as a silicon oxide layer.

In such a structure, as in the first embodiment, by causing the width of the first shape S1 of the slit widening portion to be greater than the width of the second shape, the length of the cantilever of the lower layer is shortened, and thus it is possible to reduce a risk of bending the cantilever during replacement.

Next, a method of manufacturing the semiconductor device according to the third embodiment will be described with reference to FIGS. 41 to 51. FIGS. 41 to 51 are sectional views illustrating examples of processes of manufacturing the semiconductor device according to the third embodiment.

First, as illustrated in FIG. 41, a silicon oxide film 121 is formed on the upper surface of the semiconductor substrate 80 by a chemical vapor deposition (CVD) technology or the like. Subsequently, silicon nitride films 122 and silicon oxide films 123 are alternately formed on the upper surface of the silicon oxide film 121 by a CVD technology or the like. In FIG. 41, as an example, a stacking film including the silicon nitride films 122 and the silicon oxide films 123 has a structure of two layers. The number of stacking films may be three or more.

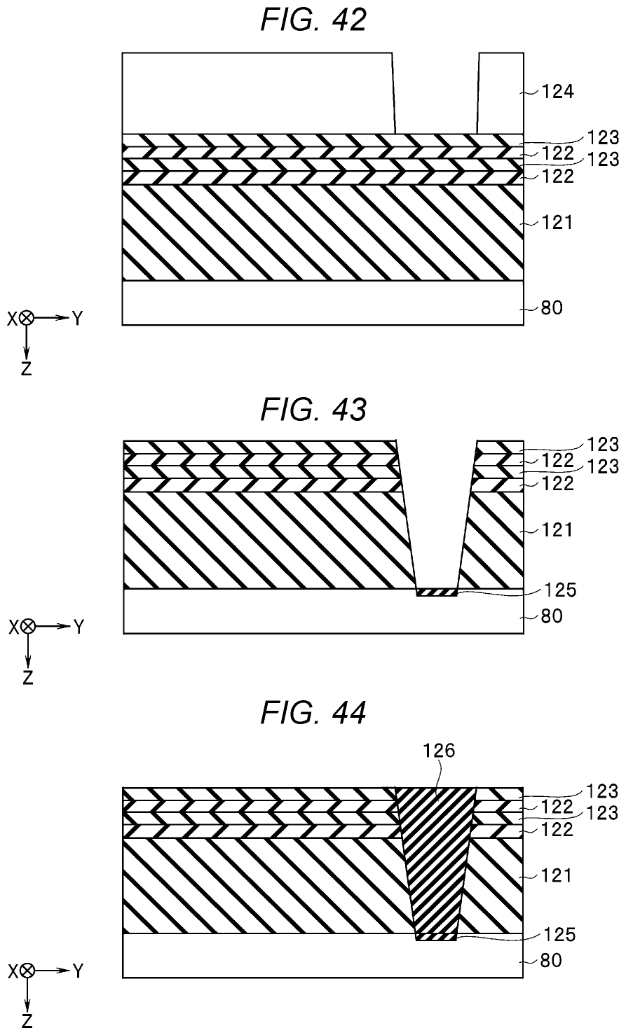

Subsequently, as illustrated in FIG. 42, an etching mask film 124 is formed on the upper surface of the uppermost silicon oxide film 123. The etching mask film 124 is, for example, an amorphous carbon film. The etching mask film 124 of a region where the slit widening portion (the first shape S1) is formed is selectively removed by a photolithographic technology and an anisotropic etching technology such as a reactive ion etching (RIE). The etching mask film 124 may be a resist film. When the etching mask film 124 is a resist film, the etching mask film 124 is formed by only a photolithographic technology. For example, after a resist is applied to the surface of the uppermost silicon oxide film 123 by a spin coat method or the like and pre-baking is performed, a pattern of the slit widening portion is transferred to the resist by an exposure technology. A developer is infiltrated and the resist in a region where a groove for the slit widening portion is formed is removed to form the etching mask film 124. At this time, the width of an opening is wider than the width of the slit ST to be formed later.

Subsequently, a region exposed from the opening of the etching mask film 124 is etched downward by an anisotropic etching technology. That is, the stacking film including the silicon nitride films 122 and the silicon oxide films 123 and the silicon oxide film 121 are etched in order. By this etching, the silicon substrate 80 is exposed on the bottom surface of the opening. When the above-described etching ends, the etching mask film 124 is removed by an anisotropic etching technology, an ashing technology, or the like. By this etching, the groove for the slit widening portion is formed.

Subsequently, a thermal oxide film 125 is formed on the surface of the silicon substrate 80 exposed to the bottom surface of the slit ST by thermal oxide processing (FIG. 43).

Subsequently, the silicon nitride film 126 is formed on the entire upper surface of the semiconductor substrate 80 by a CVD technology or the like. Subsequently, the silicon nitride film 126 is etched using the silicon oxide film 123 as a stopper by an anisotropic etching technology, a CMP technology, or the like. The silicon nitride film 126 above the position of the upper surface of the silicon oxide film 123 (the uppermost silicon oxide film 123 when the plurality of silicon oxide films 123 are formed) is removed by etching, and a silicon nitride film 126 is buried in the groove for the slit widening portion, as illustrated in FIG. 44.

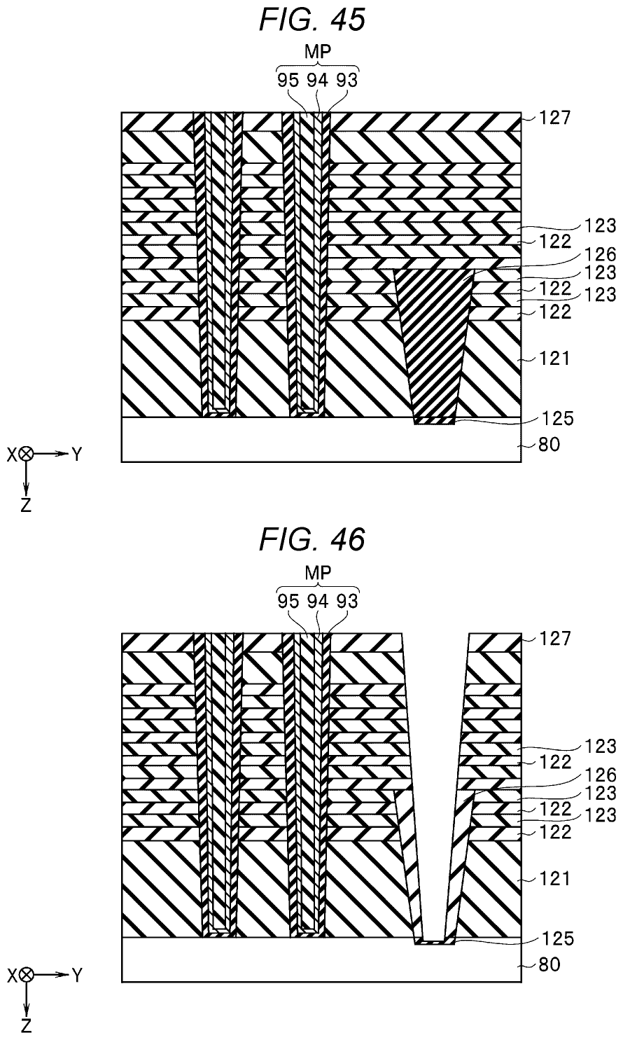

Subsequently, the silicon nitride films 122 and the silicon oxide films 123 are alternately formed by a CVD technology or the like. FIG. 45 illustrates, for example, a structure in which a stacking film including the silicon nitride films 122 and the silicon oxide films 123 is formed by five layers. Further, the silicon oxide film 127 is formed by a CVD technology or the like. An etching mask film (not illustrated) that has an opening in a region where the memory hole MH is formed is formed by a photolithographic technology, and the memory hole MH is formed by an anisotropic etching technology such as reactive ion etching (RIE). Specifically, a region exposed from an opening of the etching mask film (not illustrated) is first etched downward. That is, the silicon oxide film 127, the plurality of stacking films including the silicon nitride films 122 and the silicon oxide films 123, and the silicon oxide film 121 are etched in this order. The etching mask film is removed by an anisotropic etching technology, an ashing technology, or the like.

Subsequently, the memory pillar MP is formed in the memory hole MH. The memory pillar MP includes the memory film 93, the channel body film 94, and the core insulating film 95. First, a silicon oxide film (block insulating film), a silicon nitride film (charge trap film), and a silicon oxide f (tunnel insulating film) are formed in this order by an atomic layer deposition (ALD) method or the like. The memory film 93 is formed by these three films. Further, a polysilicon film (the channel body film 94) and a silicon oxide film (the core insulating film 95) are formed in this order by an ALD method or the like. These films are etched using the silicon oxide film 127 as a stopper by an anisotropic etching technology, a CMP technology, or the like. A film above the position of the upper surface of the silicon oxide film 127 is removed by etching, and the memory pillar MP is formed in the memory hole MH, as illustrated in FIG. 45.

Subsequently, an etching mask film (not illustrated) that has an opening in a region where the slit ST is formed is formed by a photolithographic technology, and the slit ST is formed by an anisotropic etching technology such as reactive ion etching (RIE). At this time, the width of the opening is narrower than the width of the groove for the slit widening portion. In the forming of the slit ST, the region exposed from the opening is etched downward halfway in a thermal oxide film 125. That is, the silicon oxide film 127, the plurality of stacking films including the silicon nitride films 122 and the silicon oxide films 123, the silicon oxide film 121, and the thermal oxide film 125 are etched in this order. At this time, half-etching is performed so that the thermal oxide film 125 is not penetrated. By this etching, the thermal oxide film 125 is exposed on the bottom surface of the opening. The etching mask film is removed by an anisotropic etching technology, an ashing technology, or the like (FIG. 46).

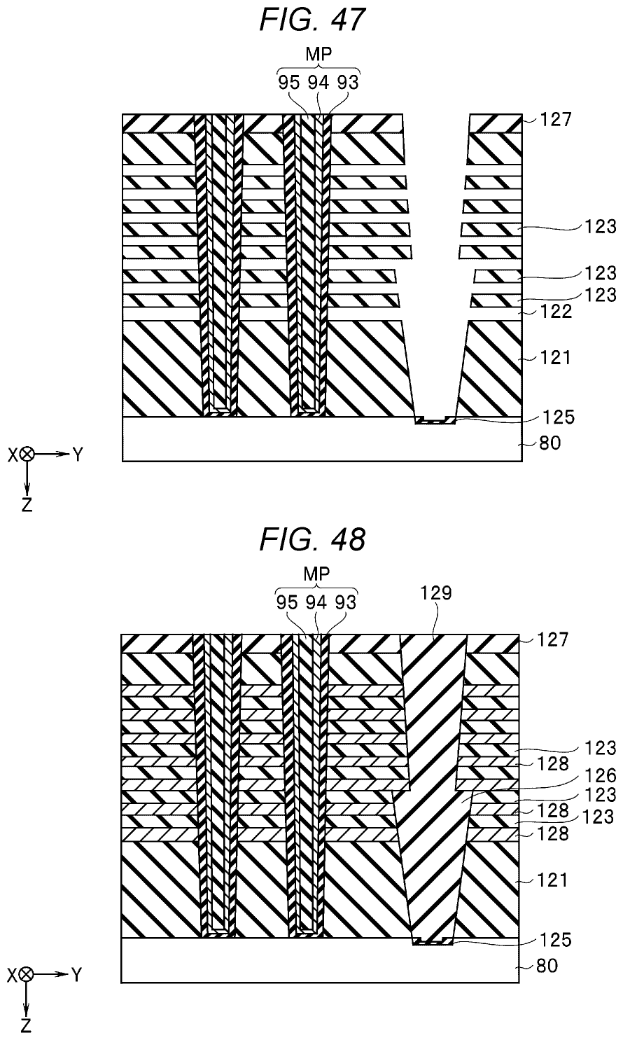

Subsequently, the silicon nitride film is selectively removed with a chemical or the like by an isotropic etching technology. By the isotropic etching technology, the silicon nitride film 126 of the widening portion is removed. The silicon nitride film 122 exposed to the side surface of the slit ST is removed. Accordingly, the cavity portion is formed in a region interposed by the inside of the slit ST and the upper and lower portions of the silicon oxide films 121, 123, and 127 (FIG. 47).

Subsequently, the cavity portion in which the silicon nitride film 122 is removed is filled with a conductive film 128 such as a tungsten film by a CVD technology or the like. The conductive film 128 functions as the source-side select gate SGS, the drain-side select gate SGD, and the word line WL. Subsequently, the entire surface is etched back by an anisotropic etching technology or the like to remove the conductive film 128 formed on the surface of the silicon oxide film 127 or in the slit ST. Subsequently, a silicon oxide film 129 is formed by a CVD technology or the like. Subsequently, the silicon oxide film 129 is etched by a CMP technology or the like. Accordingly, the silicon oxide film 129 is buried in the slit ST (FIG. 48).

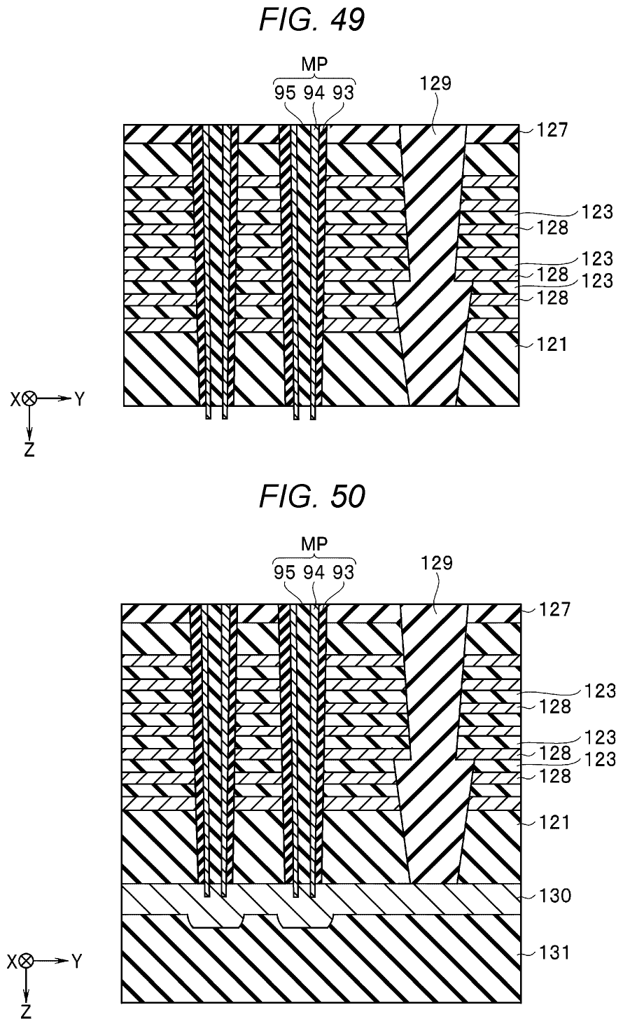

Subsequently, after an upper layer wiring (not illustrated) is formed, a chip in which a separately formed peripheral circuit is formed (for example, the controller chip 3) is pasted. Subsequently, the silicon substrate 80 and the thermal oxide film 125 are removed by a CMP technology or the like. Subsequently, the entire surface is etched back by an anisotropic etching technology or the like to remove a part of the silicon oxide film 121, a part of the memory film 93 of the memory pillar MP, and a part of the core insulating film 95 of the memory pillar MP, so that a part of the channel body film 94 of the memory pillar MP is protruded (exposed) from the silicon oxide film 121 (FIG. 49).

Finally, the polysilicon film 130 and the silicon oxide film 131 are formed in order on the upper surface of the silicon oxide film 121 by a CVD technology or the like (FIG. 50). The polysilicon film 130 functions as the source line SL. The structure illustrated in FIG. 39 is formed by performing the foregoing procedure.

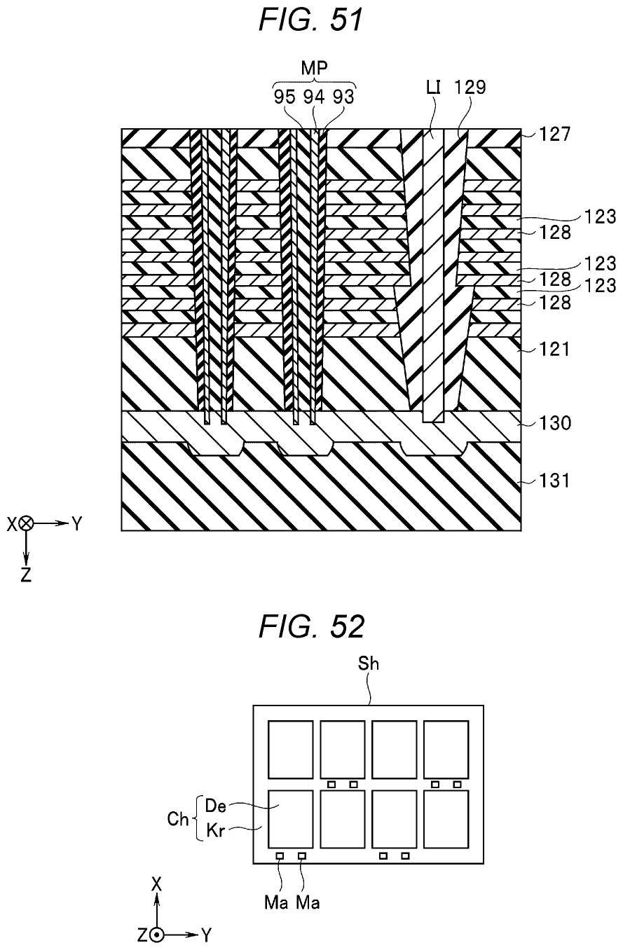

When the wiring LI through which a voltage is supplied to the source line SL is formed from a writing (not illustrated) formed above the silicon oxide film 127, a groove penetrating through the silicon oxide film 129 in the slit ST and reaching the polysilicon film 130 on the bottom of the slit ST is formed by a photolithographic technology, an etching technology, or the like. A conductive film is buried in the groove to form the wiring LI (FIG. 51). The structure illustrated in FIG. 40 is formed by performing the foregoing procedure.

In a hole of a semiconductor device manufacturing the structure according to each of the foregoing embodiments, a plurality of layers are stacked above a substrate. A device pattern and a superimposition mark are formed for each shot region in each layer. In an exposure process of the semiconductor device, to determine a pattern transfer position to an upper layer before the formation of the pattern, a reference position for the transfer position is measured using a superimposition (pattern alignment) mark of a lower layer.

FIG. 52 is a diagram illustrating an example of a shot region. As illustrated in FIG. 52, a shot region Sh includes a plurality of chip regions Ch. Each chip region Ch includes a device region De and a calf region Kr.

The calf region Kr is a region (peripheral region) disposed around the device region De. In the calf region Kr disposed around the device region De, a plurality of superimposition marks Ma are formed.

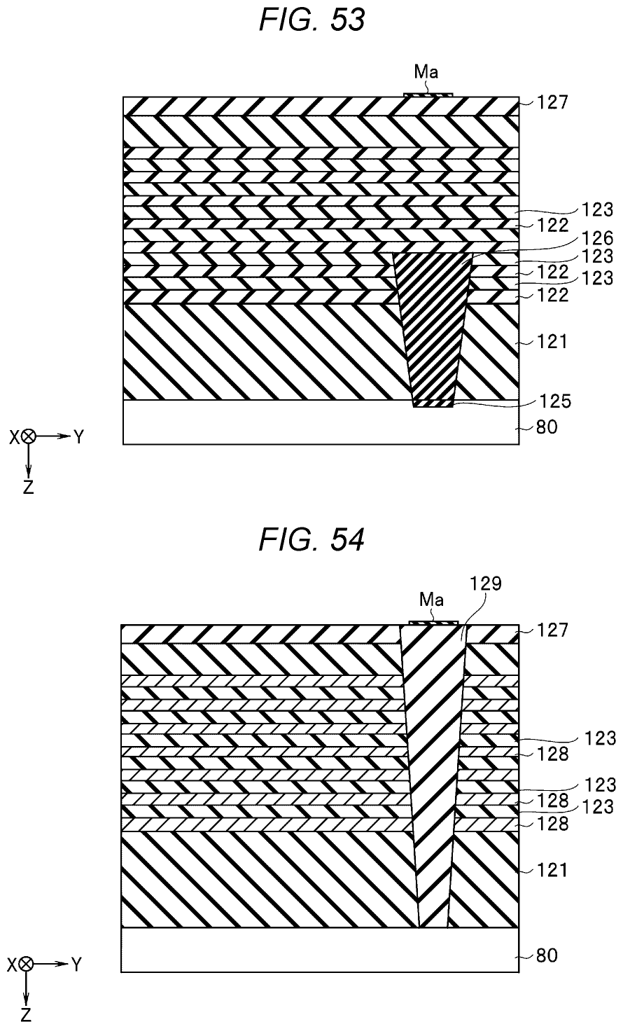

FIG. 53 is a sectional view illustrating an example of a mark of a sacrifice layer pattern. FIG. 54 is a sectional view illustrating an example of a mark of a pattern of the slit ST.

As illustrated in FIG. 53, in the mark Ma of the calf region Kr, a pattern of the slit ST on the silicon nitride film 126 which is a sacrifice layer is not disposed. Therefore, the silicon nitride film 126 which is a sacrifice layer remains without being removed, and the stacking film including the silicon nitride films 122 and the silicon oxide films 123 is formed in the upper layer of the silicon nitride film 126.

On the other hand, in the plurality of superimposition marks Ma of the pattern of the slit ST, the first shape S1 in the slit widening portion is not formed. That is, the slit ST has a shape tapered downward.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a first semiconductor layer;
a second semiconductor layer disposed over the first semiconductor layer;
a third semiconductor layer disposed over the second semiconductor layer;
a stacked body disposed over the first to third semiconductor layers and including a plurality of electrode films and a plurality of insulating films stacked alternately in a first direction;
a pillar penetrating through the stacked body in the first direction, and including a fourth semiconductor layer having a side surface in contact with the second semiconductor layer; and
a dividing structure penetrating through the stacked body in the first direction to reach the first semiconductor layer, separating the stacked body in a second direction intersecting the first direction, and further extending in a third direction intersecting the first and second directions,
wherein the dividing structure includes a first portion and a second portion located above the first portion, the first portion having a lower portion in contact with the first semiconductor layer and an upper portion located above an upper surface of the second semiconductor layer, and
wherein a width of the upper portion of the first portion in the second direction is greater than a width of the lower portion of the first portion in the second direction.

2. The semiconductor storage device according to claim 1, wherein a boundary between the first and second portions is located between a second bottommost one of the insulating films with respect to the substrate and a third bottommost one of the electrode films with respect to the substrate.

3. The semiconductor storage device according to claim 1, wherein the dividing structure separates the stacked body into a plurality of blocks.

4. The semiconductor storage device according to claim 1, wherein the dividing structure further comprises a thermal oxide film lining the lower portion of the first portion.

5. The semiconductor storage device according to claim 4, wherein the thermal oxide film is in contact with a portion of a sidewall of the first semiconductor layer and a sidewall of the second semiconductor layer.

6. The semiconductor storage device according to claim 1, wherein the fourth semiconductor layer includes a portion extending through the second semiconductor layer.

7. The semiconductor storage device according to claim 1, wherein at least the first to third semiconductor layers collectively serve as a source line.

8. The semiconductor storage device according to claim 1, wherein the pillar comprises a memory film extending along the fourth semiconductor layer, and the memory film has portions separated by the second semiconductor layer.

9. A method of manufacturing a semiconductor storage device, the method comprising:
forming a first stacked body including first, second, third, and fourth conductive layers sequentially disposed on top of one another, and further including a plurality of first insulating films and a plurality of second insulating films alternately stacked in a first direction;
forming a slit partially penetrating through the first stacked body to reach the fourth conductive layer, separating the first stacked body in a second direction intersecting the first direction, and further extending in a third direction intersecting the first and second directions;
forming a second stacked body over the first stacked body, wherein the second stacked body includes a plurality of third insulating films and a plurality of fourth insulating films alternately stacked in the first direction;
forming a pillar penetrating through both the first and second stacking bodies and including a semiconductor layer;
removing a portion of the slit and then exposing the third conductive layer;
replacing the third conductive layer with a fifth conductive layer;
removing a remaining portion of the slit; and
forming a dividing structure penetrating through both the first and second stacking bodies, separating both the first and second stacked bodies in the second direction, and further extending in the third direction, wherein the dividing structure has a first portion and a second portion, and the first portion has a lower portion with a first width of in the second direction and an upper portion with a second width in the second direction, the first width less than the second width.

10. A semiconductor storage device comprising:
a first insulating layer disposed over a substrate;
first, second, third, and fourth conductive layers sequentially disposed over the first insulating layer;
a stacked body disposed over the first to fourth conductive layers and including a plurality of electrode films and a plurality of insulating films stacked alternately in a first direction;
a pillar penetrating through the stacked body in the first direction, and including a semiconductor layer having a side surface in contact with the third conductive layer; and
a dividing structure penetrating through the stacked body in the first direction to reach the second conductive layer, separating the stacked body in a second direction intersecting the first direction, and further extending in a third direction intersecting the first and second directions,
wherein the dividing structure includes a first portion and a second portion located above the first portion, the first portion having a lower portion in contact with the second conductive layer and an upper portion located above an upper surface of the third conductive layer, and
wherein a width of the upper portion of the first portion in the second direction is greater than a width of the lower portion of the first portion in the second direction.

11. The semiconductor storage device according to claim 10, wherein a boundary between the first and second portions is located between a second bottommost one of the insulating films with respect to the substrate and a third bottommost one of the electrode films with respect to the substrate.

12. The semiconductor storage device according to claim 10, wherein the dividing structure separates the stacked body into a plurality of blocks.

13. The semiconductor storage device according to claim 10, wherein the dividing structure further comprises a thermal oxide film lining the lower portion of the first portion.

14. The semiconductor storage device according to claim 13, wherein the thermal oxide film is in contact with a portion of a sidewall of the second conductive layer and a sidewall of the third conductive layer.
